(19) United States
(12) Patent Application Publication
(10) Pub. No.: US 2025/0308973 A1
(43) Pub. Date: Oct. 2, 2025

(54) LIFT PIN SYSTEMS AND METHODS

(71) Applicant: Applied Materials, Inc., Santa Clara, CA (US)

(72) Inventors: Kaushik ALAYAVALLI, Sunnyvale, CA (US); Sumanth Kurudi GURURAJ, Hospet (IN); Vishwas BASAVARAJAIAH SOMASHEKAR, Bangalore (IN)

(21) Appl. No.: 18/618,993

(22) Filed: Mar. 27, 2024

(51) Int. Cl. H01L 21/687

(52) U.S. Cl. CPC H01L 21/68742; H01L 21/68792

(57) ABSTRACT

A substrate support assembly includes a substrate support that is moveable by a shaft between a raised position and a lowered position below the raised position. A lift pin is disposed in a hole through the substrate support, and is movable vertically with respect to the substrate support. In one implementation, the lift pin includes a shaft with a longitudinal rib. In another implementation, a lift pin system includes a seal member in a lift pin housing that forms a seal against the lift pin. In another implementation, a lift pin system is adjustable to change a distance of an end of the lift pin from a datum. In another implementation, a lift pin system includes a hoop plate to which the lift pin is coupled. The hoop plate is coupled to an actuating plate via a plunger. The actuating plate is biased against an arm coupled to the shaft.

### BACKGROUND

### Field

Embodiments of the present disclosure generally relate to lift pins for positioning a substrate relative to a substrate support in a substrate processing chamber.

### Description of the Related Art

Lift pins are typically used in semiconductor process tooling, such as a processing chamber, to support and position a substrate during substrate transfer operations. In conventional designs, the lift pins generally reside in guide holes disposed through the substrate support disposed within the processing chamber. In these conventional designs, the upper ends of the lift pins are typically flared to allow the lift pins, when positioned in a lowered position, to be positioned against a mating portion of a substrate support and prevent the pins from passing through the guide holes formed in the substrate support. The lower ends of the lift pins extend below the substrate support and are actuated by a lift plate that contacts the pins at the lower ends of the lift pins. The lift plate is movable in a vertical direction between upper and lower positions. In transitioning from the upper position to the lower position, the lift plate moves the lift pins downwards to lower a substrate onto the substrate support. In transitioning from the lower position to the upper position, the lift plate moves the lift pins upwards to extend the upper ends of the lift pins above the substrate support to contact the substrate, and raise the substrate above the substrate support to facilitate substrate transfer. Guided lift pins designs generate particles and commonly lead to eventual failure (e.g., jamming) due to the repeated interaction between surfaces of the lift pin and surfaces of the substrate support guide hole.

The lift plate is typically powered by one or more electrical or pneumatic actuators and a control system, which add complexity and cost to a processing chamber. In some instances, the lift pins do not contact the substrate simultaneously, or do not raise or lower the substrate evenly. The substrate can slip, and can be incorrectly positioned on the substrate support, which generates particles on the substrate and adversely affects the processing of the substrate. There is a need for improved systems that address such problems.

### SUMMARY

The present disclosure generally relates to lift pins for positioning a substrate relative to a substrate support in a substrate processing chamber. In one implementation, a lift pin system includes a plunger disposed in a plunger housing, and a lift pin disposed in a lift pin housing above the plunger housing. The lift pin is axially movable by movement of the plunger. The lift pin includes an upper end extending out of a top of the lift pin housing, and a lower end extending out of a bottom of the lift pin housing. A seal member is disposed in the lift pin housing, and is configured to form a seal against the lift pin.

In another implementation, a lift pin system includes a lift pin disposed in a lift pin housing. The lift pin includes an upper end extending out of a top of the lift pin housing, and a lower end extending out of a bottom of the lift pin housing. A weight is disposed at the lower end. A conical spring is disposed between the weight and the lift pin housing.

In another implementation, a substrate processing chamber includes a chamber body including a base, a substrate support disposed within the chamber body, and a lift pin system. The lift pin system includes a plunger housing coupled to the base, and a plunger disposed in the plunger housing. A lift pin housing above the plunger housing is coupled to the substrate support. A lift pin is disposed in the lift pin housing. The lift pin is axially movable by movement of the plunger The lift pin includes an upper end extending out of a top of the lift pin housing, and a lower end extending out of a bottom of the lift pin housing. A seal member is disposed in the lift pin housing, and is configured to form a seal against the lift pin.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of the scope of the disclosure, as the disclosure may admit to other equally effective embodiments.

FIG. 1 is a schematic view of a processing chamber.

FIGS. 2A, 2A-1, 2B, 2C, 2D, 2E, 2F, 2G, 2H, 2I, 2J, and 2K schematically illustrate a lift pin system that may be used in the processing chamber of FIG. 1.

FIGS. 3A, 3A-1, 3B, 3C, and 3D schematically illustrate a lift pin system that may be used in the processing chamber of FIG. 1.

FIG. 4A is a flowchart of a method of using any of the lift pin systems depicted in FIGS. 2A to 3D.

FIG. 4B is a flowchart of a method of using the lift pin system depicted FIGS. 3A to 3D.

FIGS. 5A, 5B, and 5C schematically illustrate a lift pin system that may be used in the processing chamber of FIG. 1.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure concerns lift pins for positioning a substrate relative to a substrate support in a substrate processing chamber, such as during transferring operations.

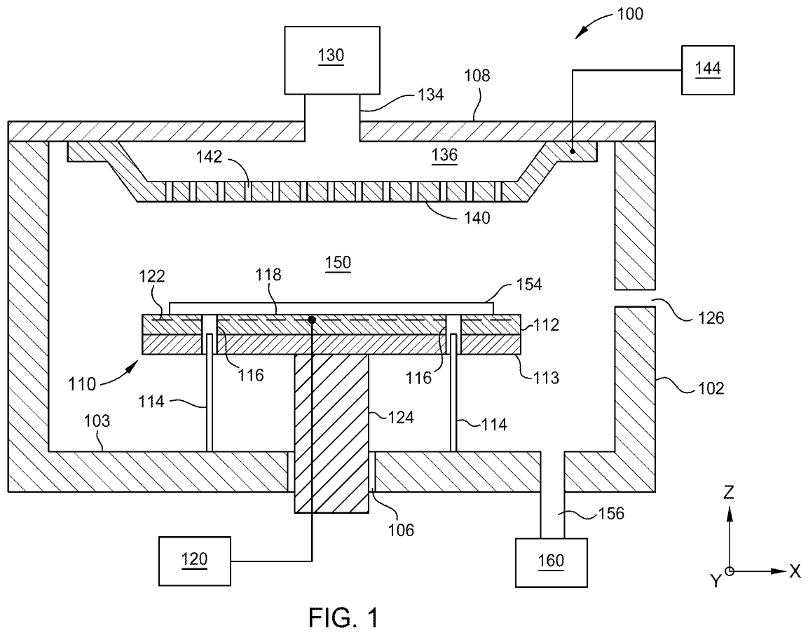

FIG. 1 illustrates a schematic cross-sectional view of a processing chamber 100. In general, the processing chamber 100 can include an atomic layer deposition (ALD) chamber, chemical vapor deposition (CVD) chamber, physical vapor deposition (PVD) chamber, etch chamber, degas chamber, an ion implantation chamber, ashing chamber, cleaning chamber, a thermal processing chamber (e.g., rapid thermal processing, anneal, cool down, thermal management control), or other type of substrate processing chamber.

However, as illustrated in FIG. 1, the processing chamber 100 is configured as a Plasma Enhanced Chemical Vapor Deposition (“PECVD”) chamber. Nevertheless, the processing chamber 100 may be configured to perform one or more other processing operations that may or may not involve a plasma. The processing chamber 100 may include relevant hardware associated with any of the above processes.

The processing chamber 100 includes a chamber body 102 with a base 103, a substrate support 110 disposed inside the chamber body 102, and a lid 108 coupled to the chamber body 102. In some embodiments, as illustrated in FIG. 1, the processing chamber 100 includes a showerhead 140 that can serve as an electrode, and is coupled to a power source 144 through a match circuit (not shown). The power source 144 is a radio frequency (RF) power source that is electrically coupled to the electrode. Further, the power source 144 provides between about 100 Watts and about 3,000 Watts at a frequency of about 50 kHz to about 15 MHz. In some embodiments, the power source 144 can be pulsed during various operations. The electrode and power source 144 facilitate control of a plasma formed within the processing volume 150.

The showerhead 140 features openings 142 for admitting a process gas or gases into a processing volume 150 from a gas supply source 130. The process gases are supplied to the processing chamber 100 via a gas feed 134, and the process gases enter a plenum 136 prior to flowing through the openings 142. In some embodiments, different process gases that are flowed simultaneously during a processing operation enter the processing chamber 100 via separate gas feeds and separate plenums prior to entering the processing volume 150 through the showerhead 140.

The gas supply source 130 includes one or more gas sources. The gas supply source 130 is configured to deliver the one or more gases from the one or more gas sources through the showerhead 140 and into the processing volume 150. Each of the one or more gas sources provides a process gas such as silane, disilane, tetraethyl orthosilicate (TEOS), germane, a metal halide (such as titanium tetrachloride, tantalum pentachloride, tungsten hexafluoride), an organometallic (such as tetrakis(dimethylamido) titanium, pentakis(dimethylamido) tantalum), ammonia, oxygen (O₂), hydrogen peroxide, hydrogen, diborane, chlorine (Cl₂), sulfur hexafluoride, a hydrocarbon (generically CₓH_{y}), among others. In some embodiments, the process gas may be ionized to form a plasma within the processing volume 150. In an example, one or more of a carrier gas and an ionizable process gas are provided into the processing volume 150 to process a substrate 154. For instance, when processing a 300 mm substrate, the process gases are introduced to the processing chamber 100 at a flow rate from about 6500 sccm to about 8000 sccm, from about 100 sccm to about 10,000 sccm, or from about 100 sccm to about 1000 sccm. Alternatively, other flow rates may be utilized. In some examples, a remote plasma source can be used to deliver plasma to the processing chamber 100 and can be coupled to the gas supply source 130.

In some embodiments, the processing chamber 100 includes a physical vapor deposition (PVD) target, which is similarly positioned as the showerhead 140 illustrated in FIG. 1, and thus takes the place of the showerhead 140. In this configuration, the PVD target serves as a sputtering material source, and is coupled to the power source 144, which is typically a DC power source. The DC power source is adapted to provide a DC voltage at a power level that is typically greater than 1 kW. A magnetron (e.g., magnet assembly not shown) is positioned behind the PVD target and is used to help control the gas ion bombardment of the lower surface of the target during processing to allow for the uniform erosion (e.g., sputtering) of the target surface during processing.

In either or any of the various possible processing chamber configurations, the substrate support 110 includes a support plate 112 that includes a support surface 118 configured to support the substrate 154 in the processing volume 150 of the processing chamber 100 during processing. In some embodiments that may be combined with other embodiments, the support plate 112 is coupled to a seal plate 113. As illustrated, in some examples, a lower surface of the support plate 112 is coupled to an upper surface of the seal plate 113. In other examples, the lower surface of the support plate 112 and the upper surface of the seal plate 113 are separated by a gap. In some embodiments that may be combined with other embodiments, the seal plate 113 is present, but is not coupled directly to the support plate 112. In some embodiments, the seal plate 113 may be omitted.

The substrate support 110 is disposed on a support shaft 124 that extends through an aperture 106 in the base 103 of the processing chamber 100. The support shaft 124 is configured to raise and lower the substrate support 110 by use of an actuator assembly (not shown) that is coupled to the support shaft 124. In some embodiments, the actuator assembly includes a guide rail (not shown) and electrical motor (not shown) or pneumatic actuator (not shown) that is configured to guide and drive the substrate support 110 in a first direction (i.e., vertical or Z direction). When the substrate support 110 is driven in the first direction, the support surface 118 is a closer distance to (or a further distance from) the base 103, or in an alternate view, is a further distance from (or a closer distance to) the showerhead 140 or the PVD target. In some embodiments that may be combined with other embodiments, the substrate support 110 is rotated by the support shaft 124 while the substrate 154 is undergoing processing in the processing chamber 100.

It is contemplated that the processing chamber 100 contains three lift pins 114, but may contain more than three lift pins 114, such as four, five, six, or more lift pins 114. Each lift pin 114 is disposed through a corresponding hole 116 in the substrate support 110, and is moveable to lift the substrate 154 off the support surface 118 to facilitate transfer of the substrate 154 into and out of the processing chamber 100. In some embodiments that may be combined with other embodiments, each of one or more of the lift pins 114 may be incorporated into a corresponding lift pin system, such as lift pin system 200, lift pin system 300, or lift pin system 500, which are described below.

The substrate 154 is provided to the processing volume 150 through an opening 126. In an example, the substrate 154 is transported into or out of the processing volume 150 using a carrier, such as a blade, that is conveyed by a robotic arm. In another example, the substrate 154 is transported into or out of the processing volume 150 using a carrier that is conveyed by magnetic levitation.

The support plate 112 contains, or is formed from, one or more metallic or ceramic materials. Exemplary metallic or ceramic materials include one or more metals, metal oxides, metal nitrides, metal oxynitrides, or any combination thereof. For example, the support plate 112 may contain or be formed from aluminum, aluminum oxide, aluminum nitride, aluminum oxynitride, or any combination thereof.

As illustrated, an electrode 122 is embedded within the support plate 112, but alternatively may be coupled to a surface (such as support surface 118) of the support plate 112. The electrode 122 is coupled to a power source 120. It is contemplated that the power source 120 may supply DC power, pulsed DC power, radio frequency (RF) power, pulsed RF power, or any combination thereof. The power source 120 is configured to drive the electrode 122 with a drive signal to generate a plasma within the processing volume 150. It is contemplated that the drive signal may be one of a DC signal and a varying voltage signal (e.g., RF signal). Further, the electrode 122 may alternatively be coupled to the power source 144 instead of the power source 120, and the power source 120 may be omitted.

In some embodiments that may be combined with other embodiments, the electrode 122 may be omitted. In some embodiments that may be combined with other embodiments, the electrode 122 (or another electrode in the support plate 112) is configured as a chucking electrode. In some embodiments that may be combined with other embodiments, the support plate 112 includes a heater, such as a resistive heating element. In some embodiments that may be combined with other embodiments, the substrate support 110 includes one or more coolant channels.

An exhaust port 156 is coupled to a vacuum pump 160. The vacuum pump 160 removes excess process gases or by-products from the processing volume 150 via the exhaust port 156 during and/or after processing.

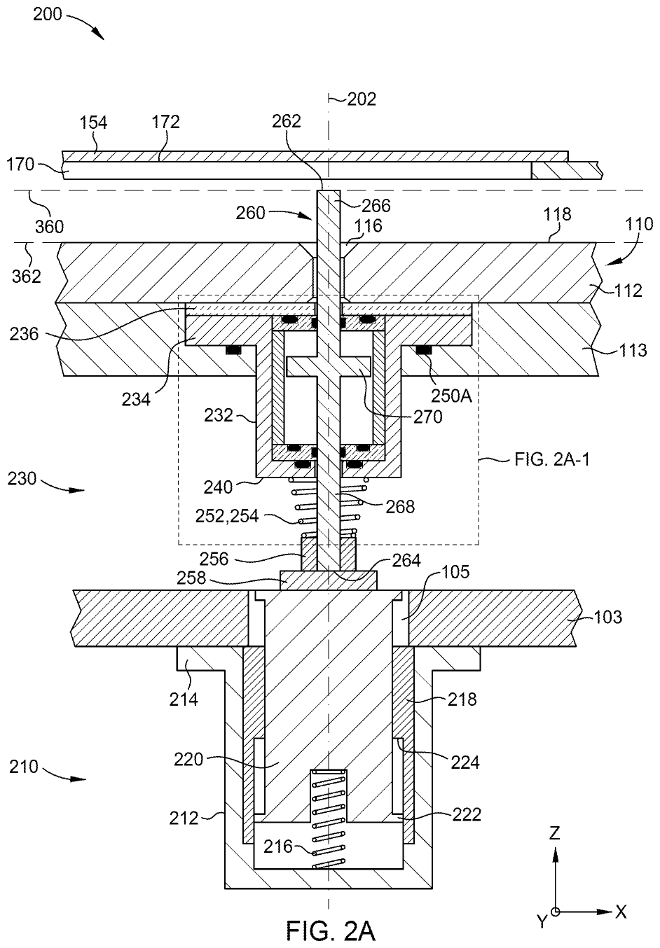

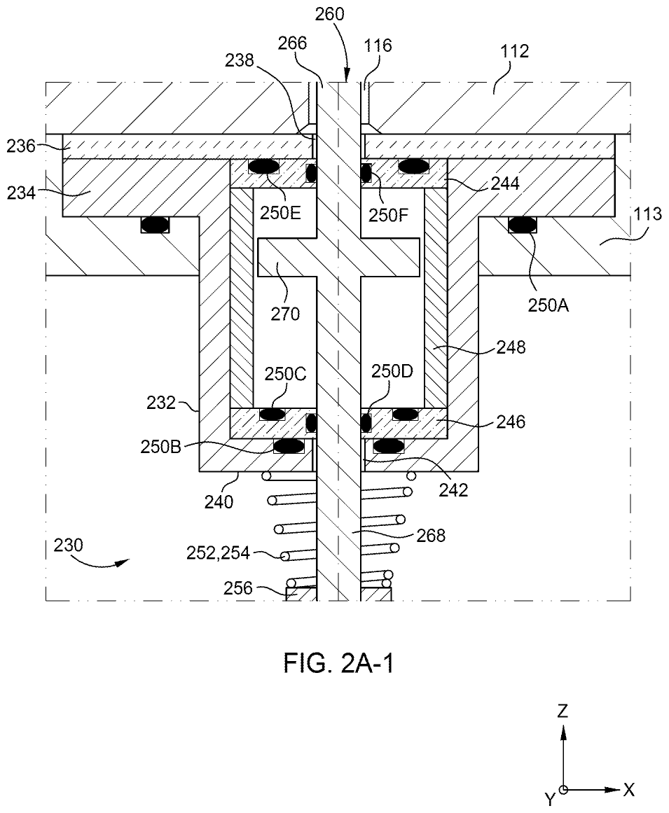

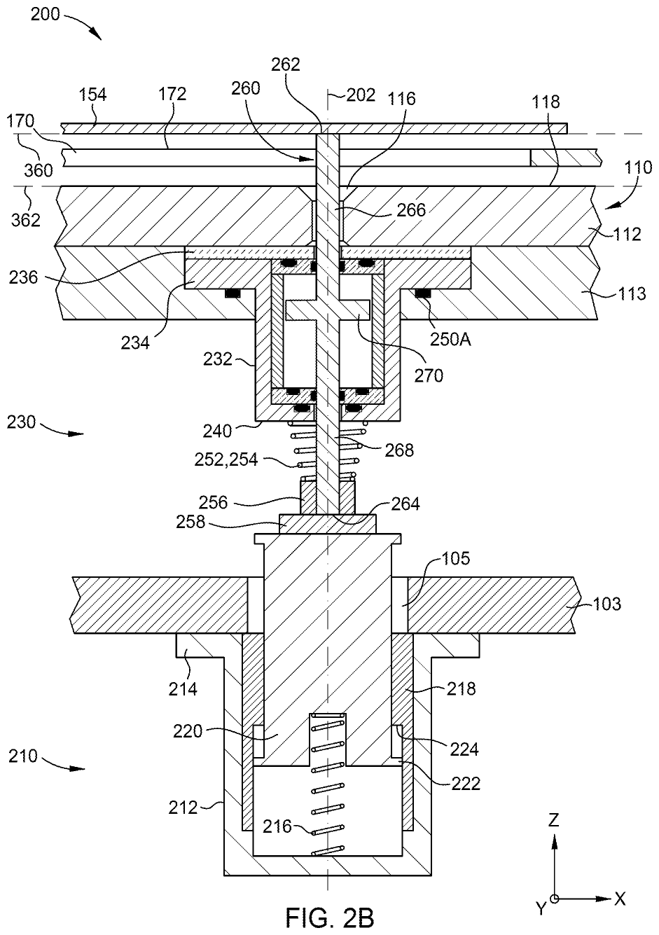

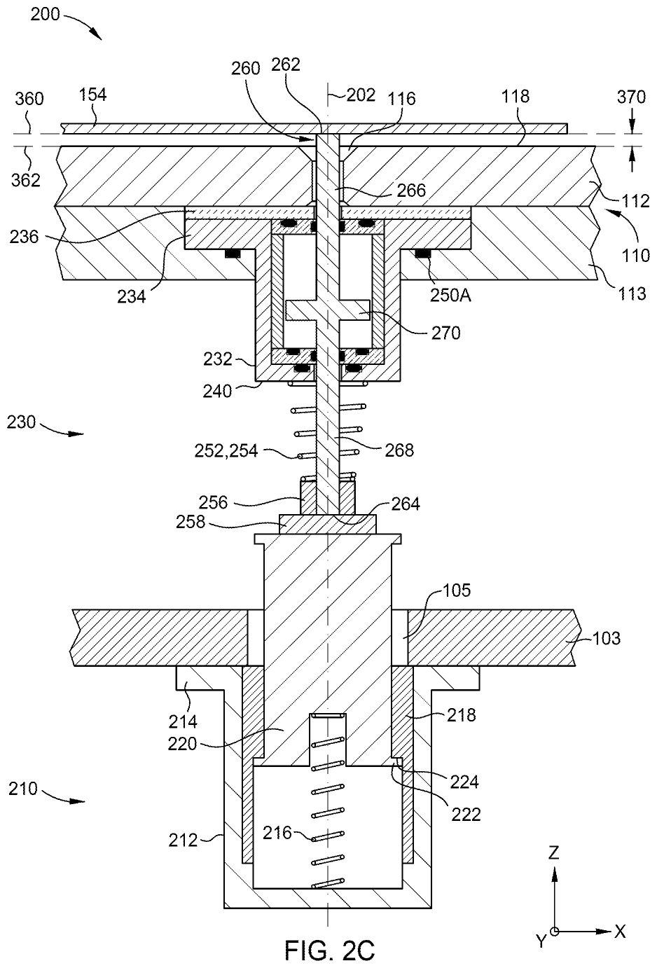

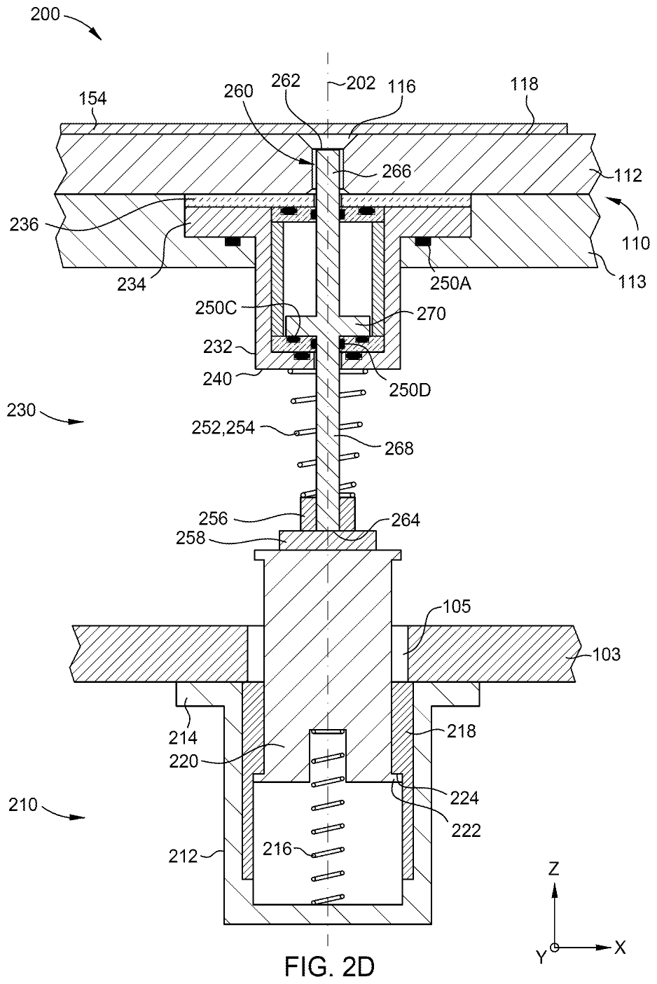

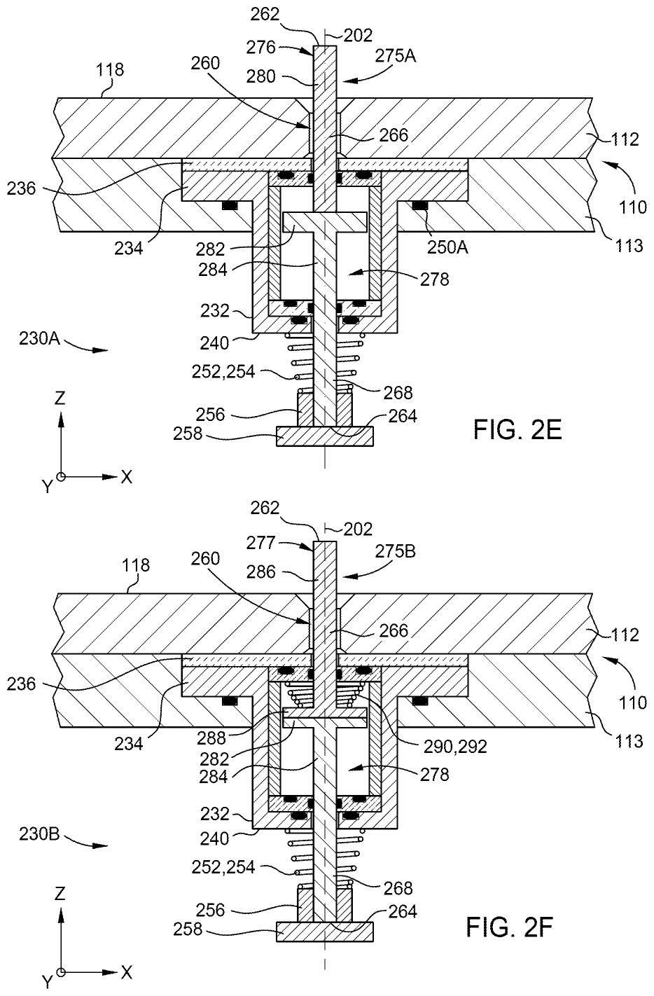

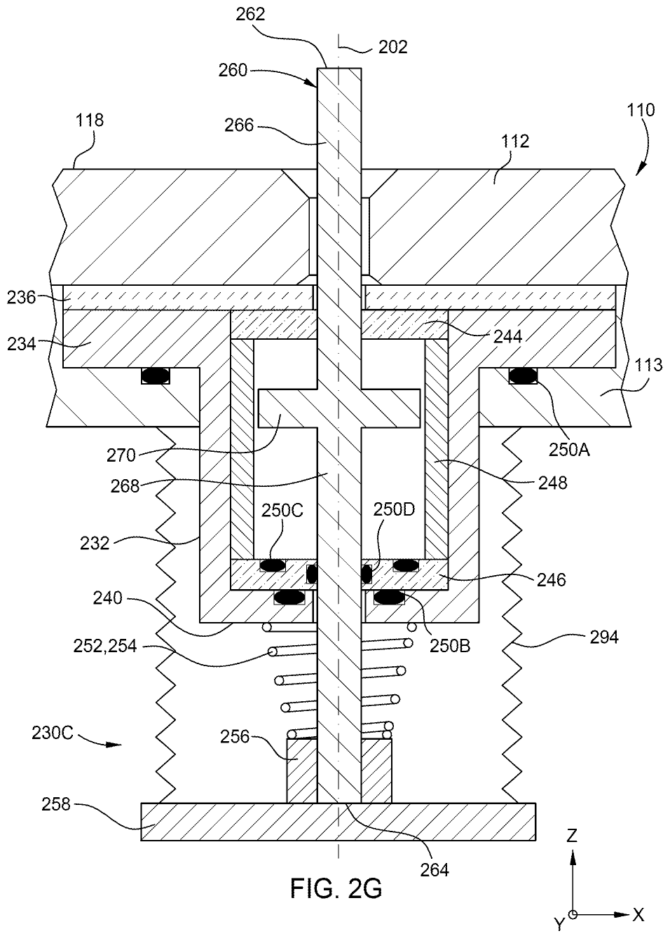

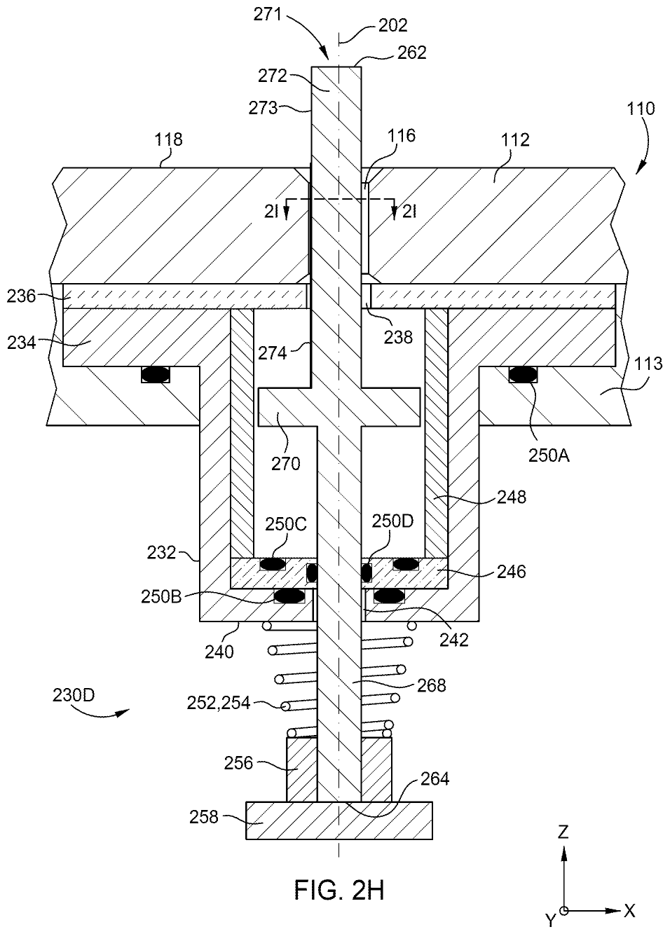

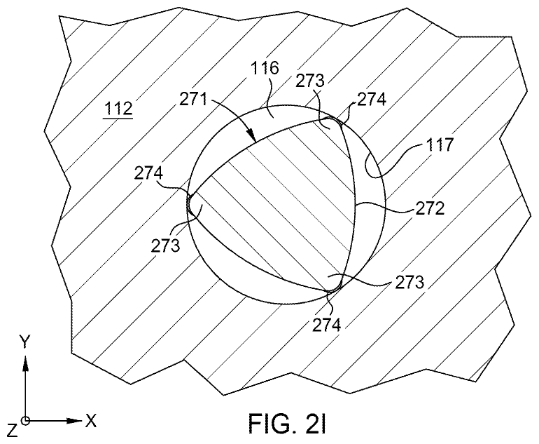

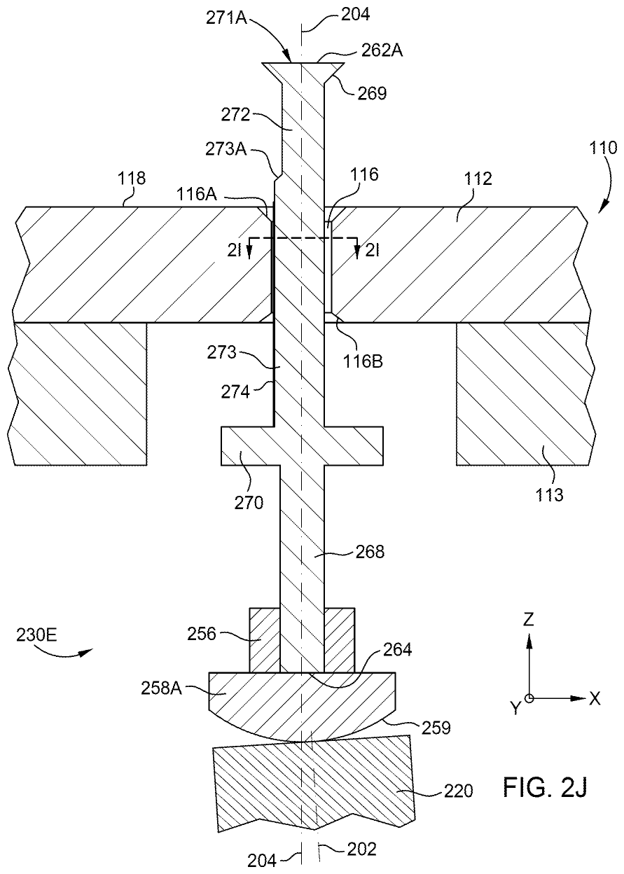

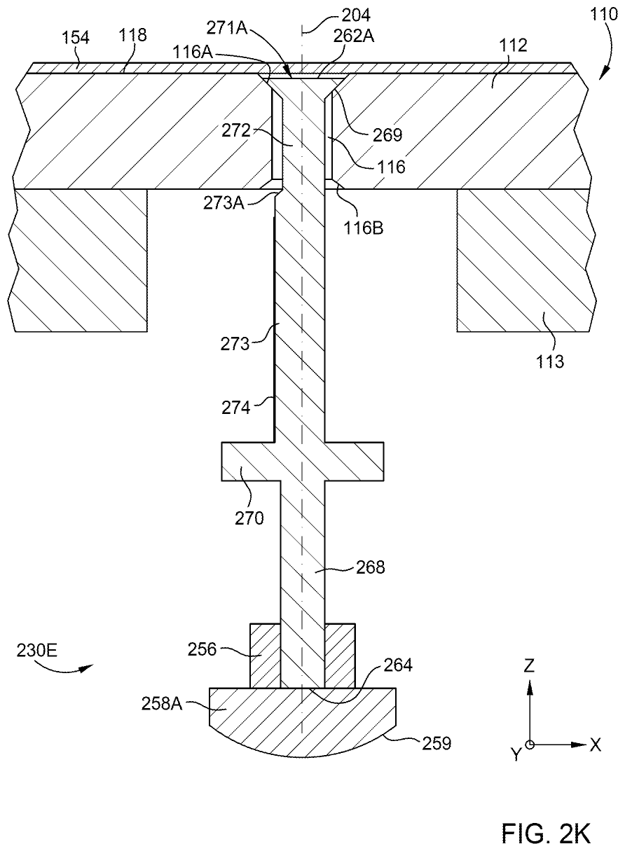

FIGS. 2A to 2D schematically illustrate a lift pin system 200 that may be used in the processing chamber 100. The processing chamber 100 may include one, two, three, four, five, six, or more lift pin systems 200. FIG. 2A shows the substrate support 110 in a lowered position. A substrate 154 is positioned on a carrier 170, such as a blade, above the substrate support 110. FIG. 2B shows the substrate support 110 in a first intermediate position above the lowered position. The substrate 154 is shown having been lifted off the carrier 170. FIG. 2C shows the substrate support 110 in a second intermediate position above the first intermediate position. The substrate 154 is shown about to be transferred to the support surface 118 of the substrate support 110. FIG. 2D shows the substrate support 110 in a raised position above the second intermediate position. The substrate 154 is shown resting on the support surface 118 of the substrate support 110.

The lift pin system 200 includes a plunger assembly 210 and a lift pin assembly 230. The plunger assembly 210 includes a plunger housing 212. The plunger housing 212 is coupled to the base 103 of the processing chamber 100, such as via a mounting flange 214. A plunger 220 is disposed in the plunger housing 212. The plunger 220 is axially movable in the plunger housing 212 along a longitudinal axis 202 of the lift pin system 200. The plunger 220 extends from the plunger housing 212 and through an aperture 105 in the base 103 of the processing chamber 100 into the processing chamber 100. The plunger 220 is biased in an upwards (“Z”) direction along the longitudinal axis 202, such as by a spring 216. In some embodiments, the plunger 220 is biased in the upwards direction by a fluid pressure. In some embodiments, the plunger 220 is biased in the upwards direction by a magnetic field.

In some embodiments, a bushing 218 in the plunger housing 212 serves as a guide for the axial movement of the plunger 220. The bushing 218 is disposed around the plunger 220. In some embodiments, the bushing 218 affects a maximum upward position of the plunger 220. In an example, the bushing 218 includes a stop shoulder 224 that provides a limit to the upward movement of the plunger 220 when contacted by a flange 222 of the plunger 220. In some embodiments, a vertical position of the stop shoulder 224 within the plunger housing 212 may be changed by replacing the bushing 218 with another bushing 218 that includes the stop shoulder 224 at a different height. In some embodiments, the bushing 218 may be omitted.

The lift pin assembly 230 is disposed above the plunger housing 212. FIG. 2A-1 provides an enlarged view of a portion of the lift pin assembly 230 depicted in FIG. 2A. Lift pin 114 (FIG. 1) is represented by lift pin 260, which is disposed in a lift pin housing 232 above the plunger housing 212. The lift pin 260 is axially movable in the lift pin housing 232 along the longitudinal axis 202 of the lift pin system 200. The lift pin housing 232 is coupled to the substrate support 110, such as via a mounting flange 234. A seal member 250A provides a seal between the substrate support 110 and the mounting flange 234. As illustrated, in some embodiments, the lift pin housing 232 is coupled to the seal plate 113 via the mounting flange 234. Additionally, or alternatively, the lift pin housing 232 may be coupled to the support plate 112 via the mounting flange 234.

In some embodiments, a cover plate 236 is disposed on the mounting flange 234. In other embodiments, the cover plate 236 is omitted. The cover plate 236 includes an aperture 238 through which the lift pin 260 extends. In some embodiments that may be combined with other embodiments, the lift pin 260 includes a shoulder 270 disposed in the lift pin housing 232, an upper shaft 266 extending above the shoulder 270 through the aperture 238 in the cover plate 236, and a lower shaft 268 extending below the shoulder 270. In some embodiments, the shoulder 270 has an outer diameter greater than an outer diameter of the upper shaft 266. In some embodiments, the shoulder 270 has an outer diameter greater than an outer diameter of the lower shaft 268. In some embodiments, the upper shaft 266, the shoulder 270, and the lower shaft 268 are integrally formed. The outer diameter of the shoulder 270 is greater than a diameter of the aperture 238 of the cover plate 236. In some embodiments that may be combined with other embodiments, the lift pin 260 does not include the shoulder 270.

The lower shaft 268 of the lift pin 260 extends downwards through an aperture 242 in a lower end 240 of the lift pin housing 232. The outer diameter of the shoulder 270 is greater than a diameter of the aperture 242 in the lower end 240 of the lift pin housing 232. A lower seal bushing 246 is disposed at the lower end 240 of the lift pin housing 232. The lower shaft 268 of the lift pin 260 extends through the lower seal bushing 246. In some embodiments, a clearance between the lower shaft 268 of the lift pin 260 and the lower seal bushing 246 is less than the clearance between the lower shaft 268 of the lift pin 260 and the aperture 242 in the lower end 240 of the lift pin housing 232. The lower seal bushing 246 may act as a guide for the lift pin 260 during axial movement of the lift pin 260, while inhibiting rubbing contact between the lower shaft 268 and the lower end 240 of the lift pin housing 232 when the lift pin 260 moves. The inhibition of rubbing contact between the lower shaft 268 and the lower end 240 of the lift pin housing 232 hinders the formation of debris particles around the lower shaft 268 in the aperture 242 in the lower end 240 of the lift pin housing 232. Hindering the formation of debris is advantageous because the debris may cause the lift pin 260 to jam, deflect, or move in a stuttering fashion, which can affect the accurate positioning of the substrate 154 onto the support surface 118 of the substrate support 110. The lower seal bushing 246 can alleviate such detrimental effects by acting as a guide for the lift pin 260 during axial movement of the lift pin 260. In some embodiments that may be combined with other embodiments, the lower seal bushing 246 acting as a guide for the lift pin 260 hinders lateral movement (e.g., X-Y) of the lift pin 260 and unwanted lateral movement of the substrate 154 when the substrate 154 is resting on the lift pin 260.

A seal member 250B provides a seal between the lower seal bushing 246 and the lift pin housing 232. In some embodiments that may be combined with other embodiments, a seal member 250C disposed in the lower seal bushing 246 is configured to make sealing contact with the shoulder 270 of the lift pin 260. In some embodiments that may be combined with other embodiments, a seal member 250D disposed in the lower seal bushing 246 is configured to make sealing contact with the lower shaft 268 of the lift pin 260. In some embodiments that may be combined with other embodiments, one of the seal member 250C or the seal member 250D may be omitted.

An upper seal bushing 244 is disposed at an upper end of the lift pin housing 232, such as at or near to the cover plate 236. The upper shaft 266 of the lift pin 260 extends through the upper seal bushing 244. In some embodiments, a clearance between the upper shaft 266 of the lift pin 260 and the upper seal bushing 244 is less than the clearance between the upper shaft 266 of the lift pin 260 and the aperture 238 in the cover plate 236. In some embodiments, a clearance between the upper shaft 266 of the lift pin 260 and the upper seal bushing 244 is less than a clearance between the upper shaft 266 of the lift pin 260 and the hole 116 in the substrate support 110. The upper seal bushing 244 may act as a guide for the lift pin 260 during axial movement of the lift pin 260, while inhibiting rubbing contact between the upper shaft 266 and the cover plate 236, and between the upper shaft 266 and the substrate support 110. The inhibition of rubbing contact between the upper shaft 266 and the cover plate 236 hinders the detrimental formation of debris particles around the upper shaft 266 in the aperture 238 in the cover plate 236. The inhibition of rubbing contact between the upper shaft 266 and the substrate support 110 hinders the detrimental formation of debris particles around the upper shaft 266 in the hole 116 in the substrate support 110.

In some embodiments that may be combined with other embodiments, a seal member 250E provides a seal between the upper seal bushing 244 and the cover plate 236. In some embodiments that may be combined with other embodiments, a seal member 250F disposed in the upper seal bushing 244 is configured to make sealing contact with the upper shaft 266 of the lift pin 260. In some embodiments that may be combined with other embodiments, one of the seal member 250E or the seal member 250F may be omitted.

Each seal member 250A, 250B, 250C, 250D, 250E, and 250F may include an o-ring, an x-ring, a lip seal, or a labyrinth seal. The seal members 250A, 250B, 250C, 250D, 250E, and 250F hinder passage of process gases to the region below the lift pin housing 232. The region below the lift pin housing 232 may be maintained at a pressure regime different from a pressure regime of the processing volume 150 of the processing chamber 100. The region below the lift pin housing 232 may be maintained as an environment that is less corrosive than an environment of the processing volume 150.

In some embodiments, a sleeve 248 in the lift pin housing 232 separates the upper seal bushing 244 and the lower seal bushing 246. In some embodiments that may be combined with other embodiments, the sleeve 248 acts as a guide for the shoulder 270 of the lift pin 260 during axial movement of the lift pin 260. In some embodiments that may be combined with other embodiments, the upper seal bushing 244 is omitted. In some embodiments that may be combined with other embodiments, the lower seal bushing 246 is omitted. In some embodiments that may be combined with other embodiments, the sleeve 248 is omitted.

Returning to FIG. 2A, a spacer 258 is disposed on the plunger 220 at a lower end 264 of the lift pin 260 below the lift pin housing 232. In some embodiments, a weight 256 is coupled to the lower shaft 268 of the lift pin 260, and is disposed on the spacer 258. In some embodiments that may be combined with other embodiments, a biasing member 252 is disposed between the lower end 240 of the lift pin housing 232 and the spacer 258. As illustrated, in some embodiments that may be combined with other embodiments, the biasing member 252 is disposed between the lower end 240 of the lift pin housing 232 and the weight 256. The biasing member 252 biases the lift pin 260 downwards towards the plunger 220. In some embodiments, the biasing member 252 is a spring, such as a cylindrical spring. As illustrated, in some embodiments, the biasing member 252 is a conical spring 254.

The conical spring 254 provides operational advantages over a conventional cylindrical spring. When compressed, particularly when approaching the minimum (or “solid”) spring length, a cylindrical spring can be prone to buckling. Buckling of the cylindrical spring may cause lateral movement of the lower end 264 of the lift pin 260 as the cylindrical spring compresses and expands. The lift pin 260 may pivot about an axis perpendicular to the longitudinal axis 202, resulting in lateral movement of an upper end 262 of the lift pin 260. Lateral movement of the upper end 262 of the lift pin 260 may cause unwanted lateral movement of the substrate 154 (when the substrate 154 is resting on the lift pin 260), and the substrate 154 may not then be correctly positioned on the substrate support 110. Incorrect positioning of the substrate 154 on the substrate support 110 can lead to non-uniform processing of the substrate 154, which can result in one or more portions of the substrate 154 being outside of required specifications and being wasted.

Additionally, buckling of the cylindrical spring can cause the cylindrical spring to rub against the lift pin 260. Such rubbing can cause abrasion of the lift pin 260, forming debris, which can be detrimental as described above. Additionally, such rubbing can cause vibrations in the lift pin 260 which are transferred to the substrate 154 when the substrate 154 is resting on the lift pin 260. Such vibrations can cause unwanted lateral movement of the substrate 154.

In contrast, the conical spring 254 does not tend to buckle when compressed. Lateral movement of the lower end 264 and upper end 262 of the lift pin 260 is alleviated. Furthermore, the conical spring 254 does not rub against the lift pin 260, and does not cause vibrations in the lift pin 260. In a test involving repeatedly placing a substrate 154 onto a substrate support 110, it was found that using a cylindrical spring as the biasing member 252 resulted in a greater variation of the position of the substrate 154 on the substrate support 110 than when using the conical spring 254 as the biasing member 252.

The lift pin housing 232 and the cover plate 236 may be made of a metallic material, such as aluminum. The lift pin 260, upper seal bushing 244, and lower seal bushing 246 may be made of a ceramic material, such as an aluminum oxide, aluminum nitride, silicon oxide, silicon nitride, or silicon carbide. The sleeve 248 may be made of a metallic material, such as aluminum. Alternatively, the sleeve 248 may be made of a ceramic material, such as an aluminum oxide, aluminum nitride, silicon oxide, silicon nitride, or silicon carbide. The biasing member 252, such as the conical spring 254, may be made of a metallic material, such as a steel, such as a carbon steel or a stainless steel. The spacer 258 may be made of a metallic material, such as aluminum or a steel, such as a carbon steel or a stainless steel. Alternatively, the spacer 258 may be made of a ceramic material, such as an aluminum oxide, aluminum nitride, silicon oxide, silicon nitride, or silicon carbide.

FIGS. 2A to 2D schematically illustrate an operational sequence in which the substrate 154 is brought into the processing chamber 100 on the carrier 170, and then transferred from the carrier 170 to the substrate support 110. It is contemplated that the processing chamber 100 includes at least one lift pin system 200 and three or more lift pins 260 in total. In some embodiments, each lift pin 260 is associated with a corresponding lift pin system 200. The upper end 262 (such as a tip) of each lift pin 260 lies on, and defines, a lift pin plane 360. Each lift pin system 200 may be adjusted, such as described above, to alter an orientation of the lift pin plane 360. The support surface 118 of the substrate support 110 lies on, and defines, a support plane 362.

FIG. 2A shows the substrate support 110 in the lowered position. The substrate 154 is disposed on an upper surface 172 of the carrier 170 above the substrate support 110. The upper end 262 of the lift pin 260 is spaced below the substrate 154 and above the support surface 118 of the substrate support 110.

FIG. 2B shows the substrate support 110 in the first intermediate position above the lowered position. The substrate support 110 has been moved upwards with respect to the base 103 of the processing chamber 100, such as by the support shaft 124 (FIG. 1). The spring 216 in the plunger housing 212 has biased the plunger 220 to move upwards along the longitudinal axis 202 of the lift pin system 200. Upward movement of the plunger 220 has moved the lift pin 260 upwards. In some embodiments, the lift pin 260 moves upwards by a distance substantially similar to the distance by which the substrate support 110 has moved upwards. In an example, the lift pin 260 moves upwards by a distance that is from 97% to 100% of the distance by which the substrate support 110 has moved upwards. In some embodiments, a force balance between the spring 216 and the biasing member 252 results in the lift pin 260 moving upwards by a distance less than the distance by which the substrate support 110 has moved upwards. In an example, the lift pin 260 moves upwards by a distance that is less than 97% of the distance by which the substrate support 110 has moved upwards.

The substrate 154 is shown having been lifted off the carrier 170 by the lift pin 260. The substrate 154 rests on the upper end 262 of the lift pin 260. In some embodiments that may be combined with other embodiments, transfer of the substrate 154 from the carrier 170 to the lift pin 260 is performed without changing an elevation of the carrier 170 (i.e. in the Z direction) within the processing chamber 100. After lifting the substrate 154 off the carrier 170, the carrier 170 is removed from the processing chamber 100.

FIG. 2C shows the substrate support 110 in the second intermediate position above the first intermediate position. The substrate support 110 has been moved upwards with respect to the base 103 of the processing chamber 100, such as by the support shaft 124 (FIG. 1). The spring 216 in the plunger housing 212 has biased the plunger 220 to move upwards along the longitudinal axis 202 of the lift pin system 200. Upward movement of the plunger 220 has been limited to a maximum upward position by the flange 222 of the plunger 220 contacting the stop shoulder 224 of the bushing 218. The plunger 220 has moved upwards by a smaller distance than the distance that the substrate support 110 has moved upwards. The weight 256 and/or biasing member 252 has driven the lift pin 260 in a downwards direction with respect to the lift pin housing 232 and the substrate support 110. The spacer 258 remains in contact with the plunger 220.

The lift pin system 200 is adjustable to change a distance of the upper end 262 of the lift pin 260 from a datum, such as the support surface 118 of the substrate support 110. When the substrate support 110 is in the second intermediate position, as depicted in FIG. 2C, a distance 370 of the upper end 262 of the lift pin 260 from the support surface 118 of the substrate support 110 is a function of (amongst other things) the length of the lift pin 260, the thickness of the spacer 258, and the maximum upward position of the plunger 220 (determined by engagement of the flange 222 of the plunger 220 with the stop shoulder 224 of the bushing 218).

Varying the distance 370 at one or more lift pin assemblies 200 in the processing chamber 100 alters the orientation of the lift pin plane 360. The distance 370 may be varied by making an adjustment to the spacer 258. In some embodiments, the adjustment includes identifying a desired thickness of the spacer 258, and installing a spacer 258 of the desired thickness. In some embodiments, the adjustment includes replacing the spacer 258 with another spacer 258 having a different thickness. In some embodiments, the adjustment includes inserting a shim (or removing a shim from) between the lift pin 260 and the spacer 258.

The distance 370 may be varied by adjusting the vertical position of the stop shoulder 224 of the bushing 218. In an example, a first bushing 218 disposed in the plunger housing 212 is replaced by a second bushing 218; the second bushing 218 having a stop shoulder 224 at a height different than the height of the stop shoulder 224 of the first bushing 218.

In some embodiments, the orientation of the lift pin plane 360 is altered to be substantially parallel to the support plane 362. For example, the lift pin plane 360 is altered such that an angle between the lift pin plane 360 and the support plane 362 is 1 degree or less, 0.5 degrees or less, 0.25 degrees or less, 0.1 degrees or less, 0.05 degrees or less, or 0 degrees. In some embodiments, the orientation of the lift pin plane 360 is substantially parallel to the support plane 362 prior to the substrate support 110 lifting the substrate off the lift pin 260.

FIG. 2D shows the substrate support 110 in the raised position above the second intermediate position. The substrate support 110 has been moved upwards with respect to the base 103 of the processing chamber 100, such as by the support shaft 124 (FIG. 1). The plunger 220 has not moved upwards. Upward movement of the plunger 220 remains limited by the flange 222 of the plunger 220 contacting the stop shoulder 224 of the bushing 218 in the plunger housing 212. The weight 256 and/or biasing member 252 has driven the lift pin 260 in a downwards direction with respect to the lift pin housing 232 and the substrate support 110. The upper end 262 of the lift pin 260 is now below the support surface 118 of the substrate support 110, and the substrate 154 has been placed onto the support surface 118.

In some embodiments, the raised position of the substrate support 110 depicted in FIG. 2D represents the position of the substrate support 110 during processing of the substrate 154. In some embodiments, the substrate support 110 is further raised above the position depicted in FIG. 2D to a processing position at which processing of the substrate 154 is conducted. As illustrated, in some embodiments, when the substrate support 110 is in the raised position, the spacer 258 remains in contact with the plunger 220. In some embodiments, when the substrate support 110 is in the raised position, the weight 256 and/or the lift pin 260 is lifted off of the spacer 258. In some embodiments, when the substrate support 110 is in the raised position, the spacer 258 is lifted off of the plunger 220. In some embodiments, when the substrate support 110 is in the processing position, the spacer 258 remains in contact with the plunger 220. In some embodiments, when the substrate support 110 is in the processing position, the weight 256 and/or the lift pin 260 is lifted off of the spacer 258. In some embodiments, when the substrate support 110 is in the processing position, the spacer 258 is lifted off of the plunger 220.

The shoulder 270 of the lift pin 260 has moved downwards with respect to the lift pin housing 232. As illustrated, in some embodiments, the shoulder 270 is moved downwards with respect to the lift pin housing 232 by a distance sufficient to cause the shoulder 270 to bear against the lower seal bushing 246. In embodiments in which the seal member 250C is present, the seal member 250C seals against the shoulder 270, and hinders passage of processing gases through the lift pin housing 232. In embodiments in which the seal member 250D is present, the seal member 250D seals against the lower shaft 268 of the lift pin 260, and hinders passage of processing gases through the lift pin housing 232. In embodiments in which the seal member 250F is present, the seal member 250F seals against the upper shaft 266 of the lift pin 260, and hinders passage of processing gases through the lift pin housing 232.

The transfer of the substrate 154 from the substrate support 110 to the carrier 170 involves performing the above operations in reverse. The substrate support 110 is moved downwards from the raised position of FIG. 2D to the second intermediate position of FIG. 2C. The biasing member 252 compresses while the downward load exerted on, and by, the plunger 220 is insufficient to overcome the upward force exerted by the spring 216. The lift pin 260 remains stationary in the Z direction, emerges through the hole 116 in the substrate support 110, and lifts the substrate 154 off the support surface 118. In some embodiments, the orientation of the lift pin plane 360 is substantially parallel to the support plane 362 prior to the lift pin 260 lifting the substrate off the substrate support 110.

The substrate support 110 is moved downwards from the second intermediate position of FIG. 2C to the first intermediate position of FIG. 2B. In some embodiments, the lift pin 260 moves downwards as soon as the substrate support 110 commences moving downwards from the second intermediate position. In some embodiments, the lift pin 260 remains stationary in the Z direction until the biasing member 252 compresses sufficiently such that the downward load exerted on, and by, the plunger 220 overcomes the upward force exerted by the spring 216. Further downward movement of the substrate support 110 is accompanied by downward movement of the plunger 220, the lift pin 260, and the substrate 154 thereon. The carrier 170 is then positioned between the substrate 154 and the support surface 118.

The substrate support 110 is moved downwards from the first intermediate position of FIG. 2B to the lowered position of FIG. 2A. The lift pin 260 moves downwards with the substrate support 110 relative to the carrier 170. The substrate 154 is then transferred from the lift pin 260 to the carrier 170. In some embodiments, the carrier 170 lifts the substrate 154 off the lift pin 260. In some embodiments, the lift pin 260 deposits the substrate 154 onto the carrier 170. In some embodiments that may be combined with other embodiments, transfer of the substrate 154 from the lift pin 260 to the carrier 170 is performed without changing an elevation of the carrier 170 (i.e., in the Z direction) within the processing chamber 100. The carrier 170 may then transport the substrate 154 out of the processing chamber 100.

In some embodiments, one or more adjustments to at least one lift pin system 200 are made prior to transferring a substrate into the processing chamber 100 for processing. In an example, the one or more adjustments are made during an initial setting-up of the processing chamber 100 prior to processing a batch of substrates. In another example, the one or more adjustments are made during the processing of a batch of substrates, such as during a pause in the processing of the batch of substrates. In another example, the one or more adjustments are made after processing a first batch of substrates and before processing a second batch of substrates.

In some embodiments that may be combined with other embodiments, the one or more adjustments to the at least one lift pin system 200 include one or more adjustments that alter the orientation of the lift pin plane 360, described above.

In some embodiments that may be combined with other embodiments, the one or more adjustments include identifying a desired thickness of the spacer 258, and installing a spacer 258 of the desired thickness. In some embodiments that may be combined with other embodiments, the one or more adjustments include replacing the spacer 258 with another spacer 258 having a different thickness. In some embodiments that may be combined with other embodiments, the one or more adjustments include inserting a shim (or removing a shim from) between the lift pin 260 and the spacer 258.

In some embodiments that may be combined with other embodiments, the one or more adjustments include changing the maximum upward position of the plunger 220. In an example, the maximum upward position of the plunger 220 is changed by replacing a first bushing 218 disposed in the plunger housing 212 with a second bushing 218; the second bushing 218 having a stop shoulder 224 at a height different than the height of the stop shoulder 224 of the first bushing 218.

FIGS. 2E to 2K schematically illustrate alternative configurations of the lift pin assembly 230. FIG. 2E depicts lift pin assembly 230A in which the lift pin 114 (FIG. 1) is represented by a split lift pin 275A. The split lift pin 275A includes an upper lift pin 276 and a lower lift pin 278. The upper lift pin 276 is movable with respect to the lower lift pin 278. In an example, the upper lift pin 276 may be removed from the lift pin assembly 230A (such as for replacement) while the lower lift pin 278 remains with the lift pin assembly 230A. The upper lift pin 276 includes an upper shaft 280 that extends through the upper seal bushing 244 in the lift pin housing 232. The lower lift pin 278 includes a lower shoulder 282 and a lower shaft 284. In some embodiments, the lower shoulder 282 and the lower shaft 284 are integrally formed. The upper lift pin 276 rests on the lower shoulder 282 in the lift pin housing 232. The lower shaft 284 extends through the lower seal bushing 246, and is coupled to the weight 256 and/or to the spacer 258. The upper lift pin 276 is made of a ceramic material, such as an aluminum oxide, aluminum nitride, silicon oxide, silicon nitride, or silicon carbide. In some embodiments, the lower lift pin 278 is made of a ceramic material, such as an aluminum oxide, aluminum nitride, silicon oxide, silicon nitride, or silicon carbide. In some embodiments, the lower lift pin 278 is made of a metallic material, such as aluminum.

FIG. 2F depicts lift pin assembly 230B in which the lift pin 114 (FIG. 1) is represented by a split lift pin 275B. The split lift pin 275B includes the lower lift pin 278 described above and an upper lift pin 277. The upper lift pin 277 is movable with respect to the lower lift pin 278. In an example, the upper lift pin 277 may be removed from the lift pin assembly 230B (such as for replacement) while the lower lift pin 278 remains with the lift pin assembly 230B. The upper lift pin 277 is made of a ceramic material, such as an aluminum oxide, aluminum nitride, silicon oxide, silicon nitride, or silicon carbide. The upper lift pin 277 includes an upper shaft 286 that extends through the upper seal bushing 244 in the lift pin housing 232. The upper shaft 286 is coupled to an upper shoulder 288. In some embodiments, the upper shaft 286 and the upper shoulder 288 are integrally formed. The upper shoulder 288 rests on the lower shoulder 282 of the lower lift pin 278 in the lift pin housing 232.

In some embodiments, a biasing member 290, such as a spring is disposed between the upper seal bushing 244 and the upper shoulder 288. As illustrated, in some embodiments, the biasing member 290 is a conical spring 292. In some embodiments that may be combined with other embodiments, the lift pin assembly 230B includes the conical spring 254 and the conical spring 292. In some embodiments that may be combined with other embodiments, one of the conical spring 254 or the conical spring 292 is present and the other of the conical spring 254 or the conical spring 292 is omitted.

FIG. 2G depicts lift pin assembly 230C. The lift pin 114 (FIG. 1) is represented by lift pin 260. In some embodiments, the lift pin 114 (FIG. 1) may be represented by split lift pin 275A or split lift pin 275B (with or without conical spring 292). In some embodiments, the lift pin 114 (FIG. 1) may be represented by lift pin 271 or lift pin 271A, described below. Lift pin assembly 230C includes a bellows 294 that extends from the seal plate 113 to the spacer 258. The bellows 294 seals against the seal plate 113 and against the spacer 258. In some embodiments, the bellows 294 extends from the lift pin housing 232 to the spacer 258, and seals against the lift pin housing 232 and against the spacer 258.

As illustrated, in some embodiments that may be combined with other embodiments, the seal members 250B, 250C, 250D, 250E, and 250F are omitted. However, in some embodiments that may be combined with other embodiments, at least one of seal member 250B, seal member 250C, seal member 250D, seal member 250E, or seal member 250F may be present. As illustrated, in some embodiments that may be combined with other embodiments, the upper seal bushing 244 is present. However, in some embodiments that may be combined with other embodiments, the upper seal bushing 244 is omitted. As illustrated, in some embodiments that may be combined with other embodiments, the lower seal bushing 246 is present. However, in some embodiments that may be combined with other embodiments, the lower seal bushing 246 is omitted. As illustrated, in some embodiments that may be combined with other embodiments, the sleeve 248 is present. However, in some embodiments that may be combined with other embodiments, the sleeve 248 is omitted.

FIGS. 2H and 2I schematically depict lift pin assembly 230D. FIG. 2I is a lateral (in the X-Y plane) cross-section of a portion of FIG. 2H. The lift pin 114 (FIG. 1) is represented by lift pin 271. In some embodiments, the lift pin 271 may be configured as split lift pin 275A or split lift pin 275B (with or without conical spring 292). The lift pin 271 includes the lower shaft 268, an upper shaft 272, and the shoulder 270 between the lower shaft 268 and the upper shaft 272. One or more longitudinal ribs 273 are disposed along the upper shaft 272. As illustrated in FIG. 2I, in some embodiments that may be combined with other embodiments, the lift pin 271 includes three longitudinal ribs 273 disposed circumferentially around the upper shaft 272. Nevertheless, it is contemplated that the lift pin 271 may include any of one, two, three, four, five, six, or more longitudinal ribs 273 disposed circumferentially around the upper shaft 272.

In some embodiments that may be combined with other embodiments, a lateral cross-sectional shape of the lower shaft 268 is different from a lateral cross-sectional shape of the upper shaft 272 with the one or more longitudinal ribs 273. In an example, the lateral cross-sectional shape of the lower shaft 268 is circular, whereas the lateral cross-sectional shape of the upper shaft 272 with the one or more longitudinal ribs 273 is non-circular. In some examples that may be combined with other examples, the lateral cross-sectional shape of the upper shaft 272 with the one or more longitudinal ribs 273 may be substantially polygonal (such as substantially triangular with convex curved sides, as illustrated). In some examples that may be combined with other examples, the lateral cross-sectional shape of the upper shaft 272 with the one or more longitudinal ribs 273 may be substantially star-shaped with convex curved sides or straight sides.

The upper shaft 272 and the one or more longitudinal ribs 273 are made of a ceramic material, such as an aluminum oxide, aluminum nitride, silicon oxide, silicon nitride, or silicon carbide. In some embodiments that may be combined with other embodiments, the upper shaft 272 and the one or more longitudinal ribs 273 are made of the same ceramic material. In some embodiments that may be combined with other embodiments, the upper shaft 272 and the one or more longitudinal ribs 273 are made of different ceramic materials. In some embodiments that may be combined with other embodiments, the one or more longitudinal ribs 273 are integrally formed with the upper shaft 272. In some embodiments that may be combined with other embodiments, the one or more longitudinal ribs 273 are bonded to the upper shaft 272.

In some embodiments that may be combined with other embodiments, the lift pin 271 includes a coating 274 on the one or more longitudinal ribs 273. In some examples, the coating 274 has a coefficient of friction that is less than a coefficient of friction of the material of the upper shaft 272. In some examples, the coating 274 has a coefficient of friction that is less than a coefficient of friction of the material of the one or more longitudinal ribs 273. In some examples, the coating 274 is an amorphous nano-composite coating, such as Diamond-Like Carbon or Titanium-Doped Molybdenum Disulfide. In some embodiments that may be combined with other embodiments, the coating 274 may be omitted.

The upper shaft 272 and the one or more longitudinal ribs 273 of the lift pin 271 are shown as being disposed in a corresponding hole 116 in the support plate 112 of the substrate support 110. As illustrated in FIG. 2I, in some embodiments that may be combined with other embodiments, each of the longitudinal ribs 273 are dimensioned such that each longitudinal rib 273 provides a stand-off of the upper shaft 272 from a sidewall 117 of the hole 116. In some examples that may be combined with other examples, each of the longitudinal ribs 273 are dimensioned such that the upper shaft 272 is substantially centralized in the hole 116. In some examples that may be combined with other examples, each of the longitudinal ribs 273 are dimensioned such that lateral movement of the upper shaft 272 (such as in the X or Y directions) within the hole 116 is hindered. It is contemplated that such guidance of the lift pin 271 while the lift pin 271 travels in the Z direction through the hole 116 hinders unwanted lateral movement of a substrate (such as substrate 154) when the substrate is resting on the lift pin 271. It is contemplated that such guidance of the lift pin 271 while the lift pin 271 travels in the Z direction through the hole 116 facilitates accurate placement of a substrate (such as substrate 154) on the support surface 118 of the substrate support 110.

As illustrated, in some embodiments that may be combined with other embodiments, the upper seal bushing 244 is omitted. However, in some embodiments that may be combined with other embodiments, the upper seal bushing 244 is present. As illustrated, in some embodiments that may be combined with other embodiments, the seal members 250E and 250F are omitted. However, in some embodiments that may be combined with other embodiments, at least one of seal member 250E or seal member 250F is present. As illustrated, in some embodiments that may be combined with other embodiments, the lower seal bushing 246 is present. However, in some embodiments that may be combined with other embodiments, the lower seal bushing 246 is omitted. As illustrated, in some embodiments that may be combined with other embodiments, the sleeve 248 is present. However, in some embodiments that may be combined with other embodiments, the sleeve 248 is omitted.

FIGS. 2J and 2K schematically depict lift pin assembly 230E. As illustrated, the lift pin housing 232, mounting flange 234, cover plate 236, upper seal bushing 244, lower seal bushing 246, sleeve 248, and biasing member 252 are omitted. The lift pin 114 (FIG. 1) is represented by lift pin 271A. In some embodiments, the lift pin 271A may be configured as split lift pin 275A or split lift pin 275B (with or without conical spring 292).

Lift pin 271A is similar to lift pin 271, including the one or more longitudinal ribs 273 disposed along the upper shaft 272, as described above. It is contemplated that the lift pin 271A may include any of one, two, three, four, five, six, or more longitudinal ribs 273 disposed circumferentially around the upper shaft 272. Each longitudinal rib 273 terminates at a top portion 273A below the upper end 262A of the lift pin 271A. In some embodiments that may be combined with other embodiments, the top portion 273A is beveled. The upper shaft 272 includes a flared portion 269 above the top portion 273A of each longitudinal rib 273. The flared portion 269 extends upwardly and outwardly towards the upper end 262A. The flared portion 269 is configured to mate with a corresponding upper tapered portion 116A of the hole 116 in the support plate 112.

The lower shaft 268 of lift pin 271A is coupled to the weight 256. In some embodiments, the lower shaft 268 of lift pin 271A is coupled to the spacer 258. As illustrated, in some embodiments, the lower shaft 268 of lift pin 271A is coupled to a spacer 258A that replaces the spacer 258. The spacer 258A includes a rounded lower surface 259. The spacer 258A is contacted by the plunger 220, as described above. The plunger 220 contacts the spacer 258A at the rounded lower surface 259 of the spacer 258A. The plunger 220 moves parallel to the longitudinal axis 202 of the lift pin system 230E, and the lift pin 271A moves parallel to the longitudinal axis 204 of the lift pin 271A. As illustrated, in some examples, the longitudinal axis 204 of the lift pin 271A and the longitudinal axis 202 of the lift pin system 230E may be angularly misaligned.

The rounded lower surface 259 of the spacer 258A facilitates a point contact between the spacer 258A and the plunger 220. In some embodiments that may be combined with other embodiments, the plunger 220 may include a rounded upper surface that facilitates point contact with the spacer 258A (or the spacer 258, if present). Such point contact accommodates angular misalignment between the longitudinal axis 204 of the lift pin 271A and the longitudinal axis 202 of the lift pin system 230E. In an example, such point contact facilitates sliding of the spacer 258A on the plunger 220 as the plunger 220 and lift pin 271A move along the corresponding longitudinal axes 202, 204.

FIG. 2K depicts the substrate support 110 in the raised position, and with a substrate 154 on the support surface 118 of the support plate 112. The lift pin 271A is suspended from the support plate 112. The flared portion 269 of the upper shaft 272 sits in an upper tapered portion 116A of the hole 116 in the support plate 112. In some embodiments that may be combined with other embodiments, the flared portion 269 of the upper shaft 272 seals against the upper tapered portion 116A of the hole 116. The upper end 262A of the lift pin 271A lies below a level of the support surface 118.

The top portion 273A of each rib 273 is below a lower tapered portion 116B of the hole 116 in the support plate 112. In the illustrated example, each rib 273 is out of the hole 116, which enables lateral movement of the lift pin 271A when the flared portion 269 of the upper shaft 272 lands in the upper tapered portion 116A of the hole 116. When the plunger 220 contacts the spacer 258A and begins to move the lift pin 271A upwards with respect to the substrate support 110, the lower tapered portion 116B of the hole 116 guides each rib 273 into the hole before the upper end 262A of the lift pin 271A contacts the substrate 154.

It is contemplated that lift pin system 200 may incorporate plunger assembly 210 in combination with any of lift pin assembly 230, lift pin assembly 230A, lift pin assembly 230B, lift pin assembly 230C, lift pin assembly 230D, or lift pin assembly 230E.

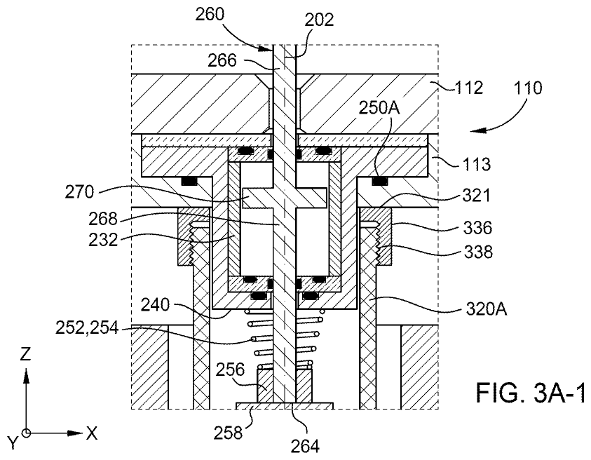

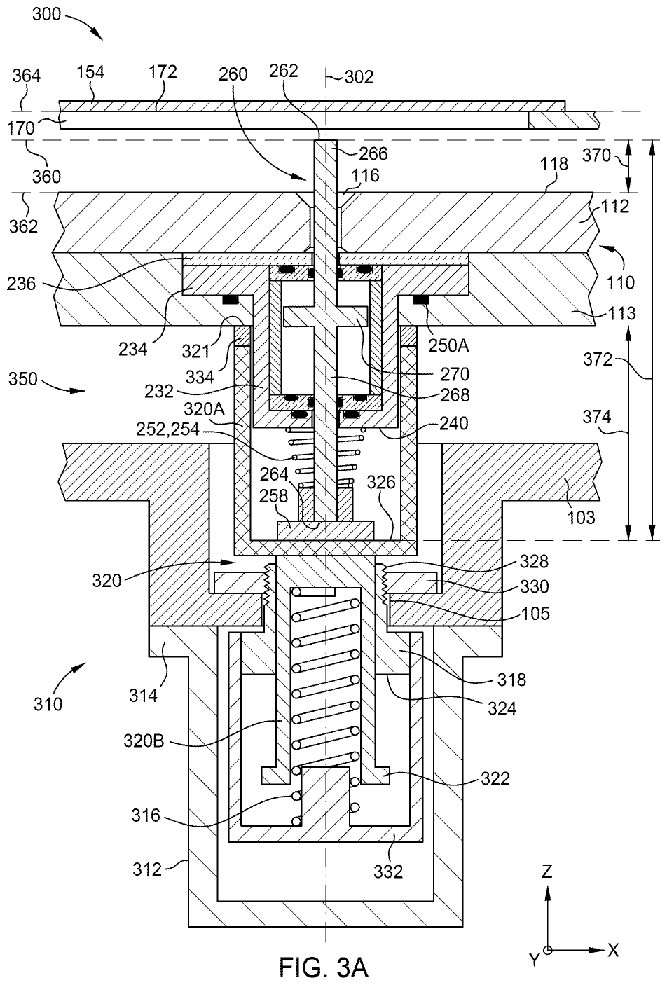

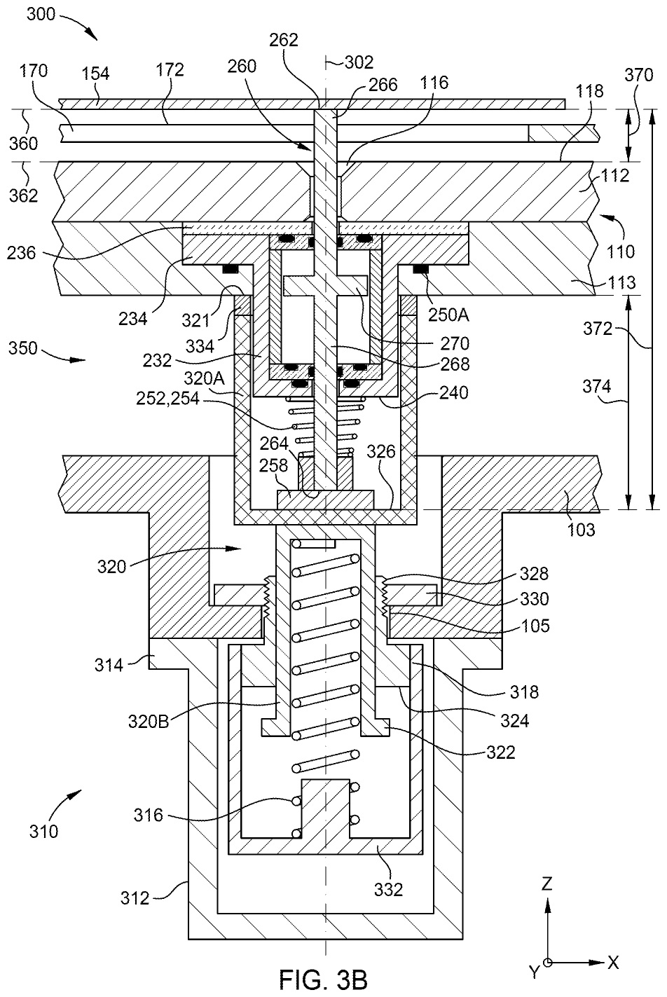

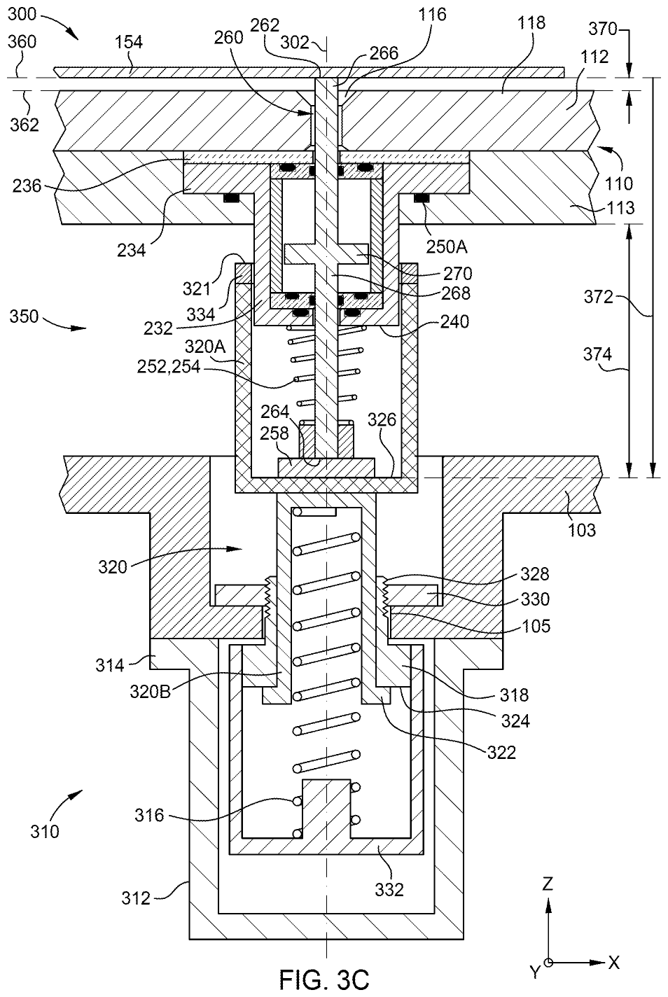

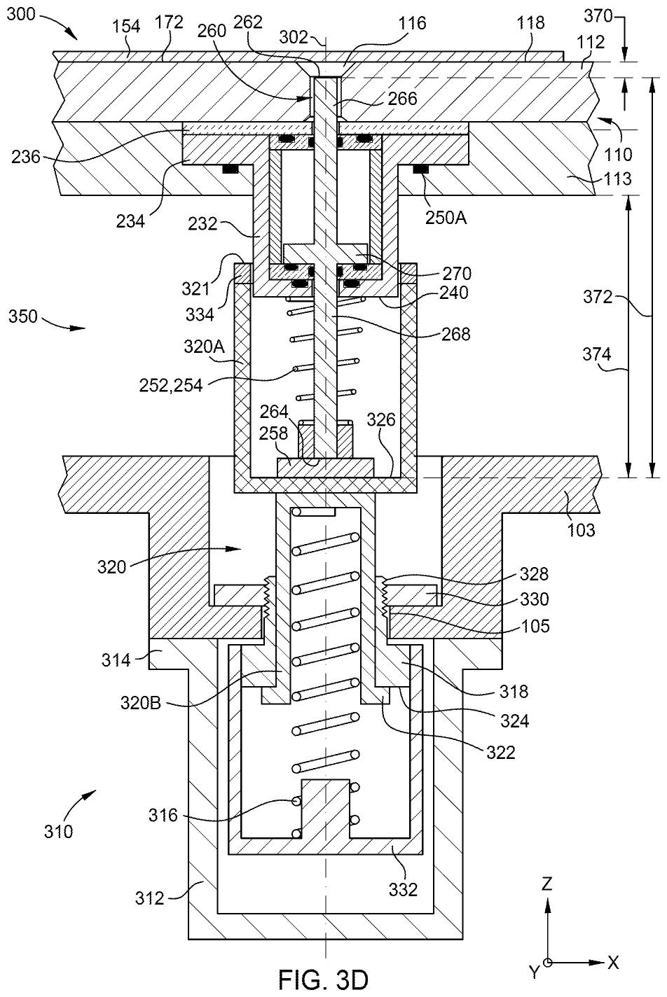

FIGS. 3A to 3D schematically illustrate a lift pin system 300 that may be used in the processing chamber 100. The processing chamber 100 may include one, two, three, four, five, six, or more lift pin systems 300. FIG. 3A shows the substrate support 110 in a lowered position. A substrate 154 is positioned on the carrier 170 above the substrate support 110. FIG. 3B shows the substrate support 110 in a first intermediate position above the lowered position. The substrate 154 is shown having been lifted off the carrier 170. FIG. 3C shows the substrate support 110 in a second intermediate position above the first intermediate position. The substrate 154 is shown about to be transferred from the lift pin to the support surface 118 of the substrate support 110. FIG. 3D shows the substrate support 110 in a raised position above the second intermediate position. The substrate 154 is shown resting on the support surface 118 of the substrate support 110.

The lift pin system 300 includes a plunger assembly 310 and a lift pin assembly 350. The plunger assembly 310 includes a plunger housing 312. The plunger housing 312 is coupled to the base 103 of the processing chamber 100, such as via a mounting flange 314. A plunger 320 includes an upper portion 320A and a lower portion 320B. The lower portion 320B is disposed in the plunger housing 312. The lower portion 320B extends from the plunger housing 312 and through the aperture 105 in the base 103 of the processing chamber 100 into the processing chamber 100. The plunger 320 is axially movable in the plunger housing 312 along a longitudinal axis 302 of the lift pin system 300. The plunger 320 is biased in an upwards (“Z”) direction along the longitudinal axis 302, such as by a spring 316. In some embodiments, the plunger 320 is biased in the upwards direction by a fluid pressure. In some embodiments, the plunger 320 is biased in the upwards direction by a magnetic field.

In some embodiments, a bushing 318 in the plunger housing 312 serves as a guide for the axial movement of the plunger 320. The bushing 318 is disposed around the lower portion 320B of the plunger 320, and affects a maximum upward position of the plunger 320. The bushing 318 includes a stop shoulder 324 that provides a limit to the upward movement of the plunger 320 when contacted by a flange 322 of the plunger 320. The bushing 318 is axially movable with respect to the plunger 320 along the longitudinal axis 302. The bushing 318 is axially movable with respect to the plunger housing 312 along the longitudinal axis 302. The maximum upward position of the plunger 320 is varied by adjusting the bushing 318. The bushing 318 is rotationally movable with respect to a nut 330, to which the bushing 318 is coupled by a thread 328. In some embodiments, the nut 330 is coupled to, or integral with, the base 103 of the processing chamber 100. Relative rotation between the nut 330 and the bushing 318 causes axial movement of the bushing 318 with respect to the plunger housing 312. In some embodiments, the nut 330 remains rotationally stationary while the bushing 318 rotates about the longitudinal axis 302. In some embodiments, the bushing 318 remains rotationally stationary while the nut 330 rotates about the longitudinal axis 302. In some embodiments, the bushing 318 or the nut 330 may be rotated by a motor.

In some embodiments that may be combined with other embodiments, the bushing 318 is coupled to a support housing 332 in the plunger housing 312. In an example, the spring 316 and the plunger 320 are disposed in the support housing 332. In some embodiments that may be combined with other embodiments, a motor rotates the support housing 332, which rotates the bushing 318. In some embodiments that may be combined with other embodiments, the support housing 332 may be omitted.

The lower portion 320B of the plunger 320 is coupled to the upper portion 320A of the plunger 320. In some embodiments, an axial length of the upper portion 320A in the direction of the longitudinal axis 302 is adjustable. In an example, the axial length of the upper portion 320A is adjusted by inserting a shim 334 in (or removing a shim 334 from) the upper portion 320A. In another example that is illustrated in FIG. 3A-1, the axial length of the upper portion 320A is adjusted by axial movement of an upper bushing 336 of the upper portion 320A with respect to the lower portion 320B. Adjustment of the upper bushing 336 may be via a thread 338, such as described above with respect to the bushing 318.

Returning to FIG. 3A, the upper portion 320A of the plunger 320 is disposed around the lift pin assembly 350. As illustrated, in some embodiments, the lift pin assembly 350 is represented by the lift pin assembly 230. In some embodiments, the lift pin assembly 350 is represented by the lift pin assembly 230A. In some embodiments, the lift pin assembly 350 is represented by the lift pin assembly 230B. In some embodiments, the lift pin assembly 350 is represented by the lift pin assembly 230C. In some embodiments, the lift pin assembly 350 is represented by the lift pin assembly 230D. In some embodiments, the lift pin assembly 350 is represented by the lift pin assembly 230E.

The lift pin system 300 is adjustable to change a distance of the upper end 262 of the lift pin 260 from a datum, such as an upward-facing surface 326 of the plunger 320. As illustrated in FIG. 3A, in some configurations of the lift pin system 300, the spacer 258 contacts the upward-facing surface 326 of the plunger 320. In some of such configurations, a distance 372 from the upward-facing surface 326 of the plunger 320 to the upper end 262 of the lift pin 260 may be adjusted by replacing the spacer 258 with another spacer 258 having a different thickness. Additionally, or alternatively, the distance 372 from the upward-facing surface 326 of the plunger 320 to the upper end 262 of the lift pin 260 may be adjusted by inserting a shim (or removing a shim from) between the lift pin 260 and the spacer 258.

FIGS. 3A to 3D schematically illustrate an operational sequence in which the substrate 154 is brought into the processing chamber 100 on the carrier 170, and then transferred from the carrier 170 to the substrate support 110. It is contemplated that the processing chamber 100 includes at least one lift pin system 300 and three or more lift pins 260 in total. In some embodiments, each lift pin 260 is associated with a corresponding lift pin system 300. The upper end 262 (such as a tip) of each lift pin 260 lies on, and defines, the lift pin plane 360 (as described above). Each lift pin system 300 may be adjusted, such as described above, to alter an orientation of the lift pin plane 360. The upper surface 172 of the carrier 170, on which the substrate 154 is transported into and out of the processing chamber 100, lies on, and defines, a carrier plane 364. The support surface 118 of the substrate support 110 lies on, and defines, the support plane 362 (as described above).

FIG. 3A shows the substrate support 110 in the lowered position. The substrate 154 is disposed on the upper surface 172 of the carrier 170 above the substrate support 110. It is contemplated that the substrate 154 lies on or parallel to the carrier plane 364. The upper end 262 of the lift pin 260 is spaced below the substrate 154 and above the support surface 118 of the substrate support 110. The spring 316 in the plunger housing 312 biases the plunger 320 upwards along the longitudinal axis 302 of the lift pin system 300. The upper end 321 of the upper portion 320A is biased into contact with the substrate support 110. The weight 256 and/or the lift pin 260 is in contact with the spacer 258 on the upward-facing surface 326 of the plunger 320.

The lift pin system 300 is adjustable to change a distance of the upper end 262 of the lift pin 260 from a datum, such as the support surface 118 of the substrate support 110. When the substrate support 110 is in the lowered position, as depicted in FIG. 3A, the distance 370 of the upper end 262 of the lift pin 260 from the support surface 118 of the substrate support 110 is a function of the length of the lift pin 260, the thickness of the spacer 258, the distance 374 from the upward-facing surface 326 of the plunger 320 to the upper end 321 of the upper portion 320A of the plunger 320, and the thickness of the substrate support 110.

Varying the distance 370 at one or more lift pin assemblies 300 in the processing chamber 100 alters an orientation of the lift pin plane 360 when the substrate support 110 is in the lowered position. The distance 370 may be varied by making adjustments to the spacer 258, as described above. The distance 370 and the distance 374 may be varied by replacing the shim 334 in the upper portion 320A, as described above. The distance 370 and the distance 374 may be varied by adjusting the upper bushing 336 of the upper portion 320, as described above.

In some embodiments, the orientation of the lift pin plane 360 is altered to be substantially parallel to the carrier plane 364. For example, the lift pin plane 360 is altered such that an angle between the lift pin plane 360 and the carrier plane 364 is 1 degree or less, 0.5 degrees or less, 0.25 degrees or less, 0.1 degrees or less, 0.05 degrees or less, or 0 degrees. In some embodiments, the orientation of the lift pin plane 360 is substantially parallel to the carrier plane 364 prior to the lift pin 260 contacting the substrate 154 that is on the carrier 170.

FIG. 3B shows the substrate support 110 in the first intermediate position above the lowered position. The substrate support 110 has been moved upwards with respect to the base 103 of the processing chamber 100, such as by the support shaft 124 (FIG. 1). The spring 316 in the plunger housing 312 has biased the plunger 320 to move upwards along the longitudinal axis 302 of the lift pin system 300. Upward movement of the plunger 320 has moved the lift pin 260 upwards. The upper end 321 of the upper portion 320A of the plunger 320 is biased into contact with the substrate support 110. The weight 256 and/or the lift pin 260 is in contact with the spacer 258 on the upward-facing surface 326 of the plunger 320. The distance 370 of the upper end 262 of the lift pin 260 from the support surface 118 of the substrate support 110 is the same as when the substrate support 110 is in the lowered position. The orientation of the lift pin plane 360 is unchanged from when the substrate support 110 is in the lowered position.

The substrate 154 is shown having been lifted off the carrier 170 by the lift pin. The substrate 154 rests on the upper end 262 of the lift pin 260. In some embodiments that may be combined with other embodiments, transfer of the substrate 154 from the carrier 170 to the lift pin 260 is performed without changing an elevation of the carrier 170 (i.e. in the Z direction) within the processing chamber 100. After lifting the substrate 154 off the carrier 170, the carrier 170 is removed from the processing chamber 100.

FIG. 3C shows the substrate support 110 in the second intermediate position above the first intermediate position. The substrate support 110 has been moved upwards with respect to the base 103 of the processing chamber 100, such as by the support shaft 124 (FIG. 1). The spring 316 in the plunger housing 312 has biased the plunger 320 to move upwards along the longitudinal axis 302 of the lift pin system 300. Upward movement of the plunger 320 has been limited to a maximum upward position by the flange 322 of the plunger 320 contacting the stop shoulder 324 of the bushing 318. The plunger 320 has moved upwards by a smaller distance than the distance that the substrate support 110 has moved upwards, and the substrate support 110 is not in contact with the upper end 321 of the upper portion 320A of the plunger 320. The weight 256 and/or biasing member 252 has driven the lift pin 260 in a downwards direction with respect to the lift pin housing 232 and the substrate support 110. The spacer 258 remains in contact with the upward-facing surface 326 of the plunger 320.

When the substrate support 110 is in the second intermediate position, as depicted in FIG. 3C, the distance 370 of the upper end 262 of the lift pin 260 from the support surface 118 of the substrate support 110 is a function of (amongst other things) the length of the lift pin 260, the thickness of the spacer 258, and the maximum upward position of the plunger 320 (determined by engagement of the flange 322 of the plunger 320 with the stop shoulder 324 of the bushing 318).

Varying the distance 370 at one or more lift pin assemblies 300 in the processing chamber 100 alters the orientation of the lift pin plane 360 when the substrate support 110 is in the second intermediate position. The distance 370 may be varied by making adjustments to the spacer 258, as described above. The distance 370 may be varied by adjusting the vertical position of the bushing 318, as described above.

In some embodiments, the orientation of the lift pin plane 360 is altered to be substantially parallel to the support plane 362. For example, the lift pin plane 360 is altered such that an angle between the lift pin plane 360 and the support plane 362 is 1 degree or less, 0.5 degrees or less, 0.25 degrees or less, 0.1 degrees or less, 0.05 degrees or less, or 0 degrees. In some embodiments, the orientation of the lift pin plane 360 is substantially parallel to the support plane 362 prior to the substrate support 110 lifting the substrate off the lift pin 260.

In some embodiments, the orientation of the carrier plane 364 is substantially parallel to the orientation of the support plane 362. In some embodiments, the orientation of the carrier plane 364 is not substantially parallel to the orientation of the support plane 362. In some embodiments that may be combined with other embodiments, the orientation of the lift pin plane 360 is substantially parallel to the carrier plane 364 prior to the lift pin 260 contacting the substrate 154 that is on the carrier 170. In some embodiments that may be combined with other embodiments, the orientation of the lift pin plane 360 is substantially parallel to the support plane 362 after the lift pin 260 lifts the substrate 154 off the carrier 170, and before the substrate support 110 lifts the substrate 154 off the lift pin 260. In some embodiments that may be combined with other embodiments, the orientation of the lift pin plane 360 changes after the lift pin 260 lifts the substrate 154 off the carrier 170, and before the substrate support 110 lifts the substrate 154 off the lift pin 260. In some embodiments, the orientation of the lift pin plane 360 changes during the transition of the substrate support 110 from the first intermediate position to the second intermediate position.

FIG. 3D shows the substrate support 110 in the raised position above the second intermediate position. The substrate support 110 has been moved upwards with respect to the base 103 of the processing chamber 100, such as by the support shaft 124 (FIG. 1). The plunger 320 has not moved upwards. Upward movement of the plunger 320 remains limited by the flange 322 of the plunger 320 contacting the stop shoulder 324 of the bushing 318. The weight 256 and/or biasing member 252 has driven the lift pin 260 in a downwards direction with respect to the lift pin housing 232 and the substrate support 110. The upper end 262 of the lift pin 260 is now below the support surface 118 of the substrate support 110, and the substrate 154 has been placed onto the support surface 118.

In some embodiments, the raised position of the substrate support 110 depicted in FIG. 3D represents the position of the substrate support 110 during processing of the substrate 154. In some embodiments, the substrate support 110 is further raised above the position depicted in FIG. 3D to a processing position at which processing of the substrate 154 is conducted. As illustrated, in some embodiments, when the substrate support 110 is in the raised position, the spacer 258 remains in contact with the upward-facing surface 326 of the plunger 320. In some embodiments, when the substrate support 110 is in the raised position, the weight 256 and/or the lift pin 260 is lifted off of the spacer 258. In some embodiments, when the substrate support 110 is in the raised position, the spacer 258 is lifted off of the upward-facing surface 326 of the plunger 320. In some embodiments, when the substrate support 110 is in the processing position, the spacer 258 remains in contact with the upward-facing surface 326 of the plunger 320. In some embodiments, when the substrate support 110 is in the processing position, the weight 256 and/or the lift pin 260 is lifted off of the spacer 258. In some embodiments, when the substrate support 110 is in the processing position, the spacer 258 is lifted off of the upward-facing surface 326 of the plunger 320.

The shoulder 270 of the lift pin 260 has moved downwards with respect to the lift pin housing 232. As illustrated, in some embodiments, the shoulder 270 is moved downwards with respect to the lift pin housing 232 by a distance sufficient to cause the shoulder 270 to bear against the lower seal bushing 246. In embodiments in which the seal member 250C is present, the seal member 250C seals against the shoulder 270, and hinders passage of processing gases through the lift pin housing 232. In embodiments in which the seal member 250D is present, the seal member 250D seals against the lower shaft 268 of the lift pin 260, and hinders passage of processing gases through the lift pin housing 232. In embodiments in which the seal member 250F is present, the seal member 250F seals against the upper shaft 266 of the lift pin 260, and hinders passage of processing gases through the lift pin housing 232.

The transfer of the substrate 154 from the substrate support 110 to the carrier 170 involves performing the above operations in reverse. The substrate support 110 is moved downwards from the raised position of FIG. 3D to the second intermediate position of FIG. 3C. The lift pin 260 remains stationary in the Z direction, emerges through the hole 116 in the substrate support 110, and lifts the substrate 154 off the support surface 118. In some embodiments, the orientation of the lift pin plane 360 is substantially parallel to the support plane 362 prior to the lift pin 260 lifting the substrate 154 off the substrate support 110.

The substrate support 110 is moved downwards from the second intermediate position of FIG. 3C to the first intermediate position of FIG. 3B. The lift pin 260 remains stationary in the Z direction until the substrate support 110 contacts the upper end 321 of the upper portion 320A of the plunger 320. Further downward movement of the substrate support 110 is accompanied by downward movement of the plunger 320, the lift pin 260, and the substrate 154 thereon. The carrier 170 is then positioned between the substrate 154 and the support surface 118.

In some embodiments that may be combined with other embodiments, the orientation of the lift pin plane 360 changes during the transition of the substrate support 110 from the second intermediate position to the first intermediate position. In some embodiments that may be combined with other embodiments, the orientation of the lift pin plane 360 changes after the lift pin 260 lifts the substrate 154 off the substrate support 110, and before the substrate 154 is then transferred from the lift pin 260 to the carrier 170. In some embodiments that may be combined with other embodiments, the orientation of the lift pin plane 360 is substantially parallel to the support plane 362 prior to the lift pin 260 lifting the substrate off the substrate support 110. In some embodiments that may be combined with other embodiments, the orientation of the lift pin plane 360 is substantially parallel to the carrier plane 364 between the lift pin 260 lifting the substrate 154 off the substrate support 110 and the transferring of the substrate 154 from the lift pin 260 to the carrier 170.

The substrate support 110 is moved downwards from the first intermediate position of FIG. 3B to the lowered position of FIG. 3A. The lift pin 260 moves downwards with the substrate support 110 relative to the carrier 170. The substrate 154 is then transferred from the lift pin 260 to the carrier 170. In some embodiments, the carrier 170 lifts the substrate 154 off the lift pin 260. In some embodiments, the lift pin 260 deposits the substrate 154 onto the carrier 170. In some embodiments that may be combined with other embodiments, transfer of the substrate 154 from the lift pin 260 to the carrier 170 is performed without changing an elevation of the carrier 170 (i.e., in the Z direction) within the processing chamber 100. The carrier 170 may then transport the substrate 154 out of the processing chamber 100.

In some embodiments, one or more adjustments to at least one lift pin system 300 are made prior to transferring a substrate 154 into the processing chamber 100 for processing. In an example, the one or more adjustments are made during an initial setting-up of the processing chamber 100 prior to processing a batch of substrates 154. In another example, the one or more adjustments are made during the processing of a batch of substrates 154, such as during a pause in the processing of the batch of substrates 154. In another example, the one or more adjustments are made after processing a first batch of substrates 154 and before processing a second batch of substrates 154.

In some embodiments that may be combined with other embodiments, the one or more adjustments to the at least one lift pin system 300 include one or more adjustments that alter the orientation of the lift pin plane 360, described above.

In some embodiments that may be combined with other embodiments, the one or more adjustments include identifying a desired thickness of the spacer 258, and installing a spacer 258 of the desired thickness. In some embodiments that may be combined with other embodiments, the one or more adjustments include replacing the spacer 258 with another spacer 258 having a different thickness. In some embodiments that may be combined with other embodiments, the one or more adjustments include inserting a shim (or removing a shim from) between the lift pin 260 and the spacer 258.

In some embodiments that may be combined with other embodiments, the one or more adjustments include changing the axial length of the upper portion 320A of the plunger 320. In an example, the axial length of the upper portion 320A is changed by inserting a shim 334 in (or removing a shim 334 from) the upper portion 320A. In another example, the axial length of the upper portion 320A is changed by adjusting the upper bushing 336 of the upper portion 320A.

In some embodiments that may be combined with other embodiments, the one or more adjustments include changing the maximum upward position of the plunger 320. In an example, the maximum upward position of the plunger 320 is changed by adjusting the bushing 318 disposed around the lower portion 320B of the plunger 320, such as described above.

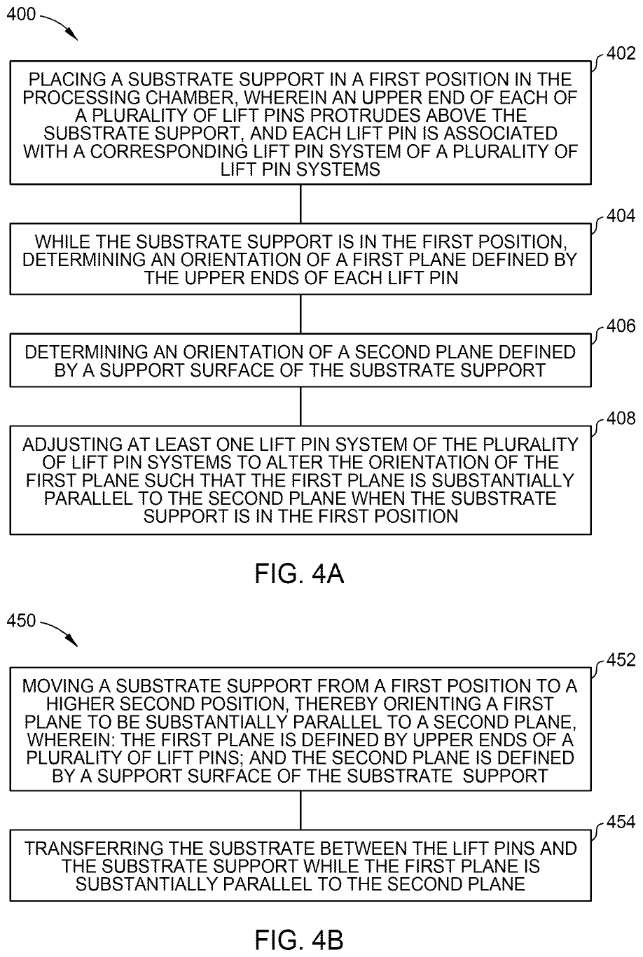

FIG. 4A is a flowchart of a method 400 of configuring a processing chamber, such as processing chamber 100. Operation 402 includes placing a substrate support in a first position in the processing chamber. An upper end of each of a plurality of lift pins protrudes above the substrate support. Each lift pin is associated with a corresponding lift pin system of a plurality of lift pin systems.

In some embodiments, the substrate support is the substrate support 110. In some embodiments that may be combined with other embodiments, the plurality of lift pin systems includes at least one lift pin system 200, and the first position corresponds to the second intermediate position of the substrate support 110 depicted in FIG. 2C. In some embodiments that may be combined with other embodiments, the plurality of lift pin systems includes at least one lift pin system 300, and the first position corresponds to the second intermediate position of the substrate support 110 depicted in FIG. 3C. In some embodiments that may be combined with other embodiments, the lift pins include a lift pin configured as one of lift pin 260, split lift pin 275A, split lift pin 275B, lift pin 271, or lift pin 271A.

Operation 404 includes, while the substrate support is in the first position, determining an orientation of a first plane defined by the upper ends of each lift pin. In an example, the upper ends of each lift pin are upper ends 262, and the first plane is the lift pin plane 360. In some embodiments, operation 404 includes placing a flat plate (such as a flat substrate or a flat dummy substrate) on the upper end of each lift pin, and measuring a distance of each of a plurality of locations on the flat plate from a datum. In an example, the distance of each location on the flat plate from the datum is measured optically.

Operation 406 includes determining an orientation of a second plane defined by a support surface of the substrate support. In an example, the support surface is support surface 118 of substrate support 110, and the second plane is the support plane 362. In some embodiments, operation 406 includes measuring a distance of each of a plurality of locations on the support surface from the datum. In an example, the distance of each location on the support surface from the datum is measured optically.

Operation 408 includes adjusting at least one lift pin system of the plurality of lift pin systems to alter the orientation of the first plane such that the first plane is substantially parallel to the second plane when the substrate support is in the first position. In some embodiments, adjusting the at least one lift pin system includes changing a maximum upward position of a plunger of the at least one lift pin system, such as described above. In some embodiments, adjusting the at least one lift pin system includes making one or more adjustments to a spacer (e.g., the spacer 258), such as described above.

In some embodiments that may be combined with other embodiments, method 400 includes placing the substrate support in a second position below the first position in the processing chamber. In some embodiments in which the plurality of lift pin systems includes at least one lift pin system 200, the second position corresponds to the lowered position of the substrate support 110 depicted in FIG. 2A. In some embodiments in which the plurality of lift pin systems includes at least one lift pin system 200, the second position corresponds to the first intermediate position of the substrate support 110 depicted in FIG. 2B. In some embodiments in which the plurality of lift pin systems includes at least one lift pin system 300, the second position corresponds to the lowered position of the substrate support depicted in FIG. 3A. In some embodiments in which the plurality of lift pin systems includes at least one lift pin system 300, the second position corresponds to the first intermediate position of the substrate support 110 depicted in FIG. 3B.

In some embodiments that may be combined with other embodiments, method 400 includes, while the substrate support is in the second position, determining the orientation of the first plane. In some embodiments that may be combined with other embodiments, method 400 includes determining an orientation of a third plane defined by a surface of a substrate carrier. In an example, the substrate carrier is the carrier 170, the surface is upper surface 172, and the third plane is the carrier plane 364. In some embodiments, determining the orientation of the third plane includes measuring a distance of each of a plurality of locations on the surface of the substrate carrier from the datum. In an example, the distance of each location of the surface of the substrate carrier from the datum is measured optically.

In some embodiments that may be combined with other embodiments, method 400 includes adjusting at least one lift pin system of the plurality of lift pin systems to alter the orientation of the first plane such that the first plane is substantially parallel to the third plane when the substrate support is in the second position.

In some embodiments, adjusting the at least one lift pin system includes making one or more adjustments to a spacer (e.g., the spacer 258), such as described above. In some embodiments, adjusting the at least one lift pin system includes changing a distance between the substrate support and an upward-facing surface of a plunger of the at least one lift pin system. In an example, changing the distance between the substrate support and the upward-facing surface of the plunger includes changing an axial length of a portion of the plunger, such as described above.

In some embodiments, one or more activities of the method 400 are performed prior to transferring a substrate into the processing chamber for processing. In an example, the one or more activities are performed during an initial setting-up of the processing chamber prior to processing a batch of substrates. In another example, the one or more activities are performed during the processing of a batch of substrates, such as during a pause in the processing of the batch of substrates. In another example, the one or more activities are performed after processing a first batch of substrates and before processing a second batch of substrates.

FIG. 4B is a flowchart of a method 450 of operating a processing chamber, such as processing chamber 100. Operation 452 includes moving a substrate support from a first position to a higher second position, thereby orienting a first plane to be substantially parallel to a second plane. In some embodiments, the substrate support is the substrate support 110. The first plane is defined by upper ends of a plurality of lift pins. In some embodiments, the lift pins include a lift pin configured as one of lift pin 260, split lift pin 275A, split lift pin 275B, lift pin 271, or lift pin 271A. In an example, the upper ends of each lift pin are upper ends 262, and the first plane is the lift pin plane 360. The second plane is defined by a support surface of the substrate support. In an example, the support surface is support surface 118 of substrate support 110, and the second plane is the support plane 362.

In some embodiments that may be combined with other embodiments, at least one lift pin of the plurality of lift pins is associated with a lift pin system. In some examples that may be combined with other examples, the lift pin system is lift pin system 200. In some of such examples, the first position corresponds to the lowered position of the substrate support 110 depicted in FIG. 2A. In some of such examples, the first position corresponds to the first intermediate position of the substrate support 110 depicted in FIG. 2B. In some of such examples, the second position corresponds to the second intermediate position of the substrate support 110 depicted in FIG. 2C. In some of such examples, the second position corresponds to the raised position of the substrate support 110 depicted in FIG. 2D.

In some examples that may be combined with other examples, the lift pin system is lift pin system 300. In some of such examples, the first position corresponds to the lowered position of the substrate support 110 depicted in FIG. 3A. In some of such examples, the first position corresponds to the first intermediate position of the substrate support 110 depicted in FIG. 3B. In some of such examples, the second position corresponds to the second intermediate position of the substrate support 110 depicted in FIG. 3C. In some of such examples, the second position corresponds to the raised position of the substrate support 110 depicted in FIG. 3D.

In some embodiments that may be combined with other embodiments, orienting the first plane to be substantially parallel to the second plane includes moving first and second lift pins of the plurality of lift pins upwards with the substrate support, and stopping upward movement of the first lift pin while the substrate support and the second lift pin continue moving upwards. In an example, stopping upward movement of the first lift pin includes engaging a stop shoulder with a flange of a plunger that is associated with the first lift pin, such as described above with respect to lift pin system 200 or lift pin system 300.

In some embodiments that may be combined with other embodiments, orienting the first plane to be substantially parallel to the second plane further includes stopping upward movement of the second lift pin while the substrate support continues moving upwards. In an example, stopping upward movement of the second lift pin includes engaging a stop shoulder with a flange of a plunger that is associated with the second lift pin, such as described above with respect to lift pin system 200 or lift pin system 300.

Operation 454 includes transferring the substrate between the lift pins and the substrate support while the first plane is substantially parallel to the second plane. In some embodiments that may be combined with other embodiments, operation 454 includes transferring the substrate from the lift pins to the substrate support. In an example, the substrate is disposed on the upper ends of the lift pins, and operation 454 includes raising the substrate support beyond the second position while the lift pins remain stationary, and lifting the substrate off the lift pins with the substrate support.

In some embodiments that may be combined with other embodiments, operation 454 includes transferring the substrate from the substrate support to the lift pins. In an example, the substrate is disposed on the support surface of the substrate support, and operation 454 includes lowering the substrate support towards the first position while the lift pins remain stationary, and lifting the substrate off the substrate support with the lift pins.

In some embodiments that may be combined with other embodiments, method 450 includes moving the substrate support from the second position towards the first position, thereby orienting the first plane to be substantially parallel to a third plane defined by a surface of a substrate carrier. In an example, the substrate carrier is the carrier 170, the surface is upper surface 172, and the third plane is the carrier plane 364.

In some embodiments that may be combined with other embodiments, orienting the first plane to be substantially parallel to the third plane includes moving the second lift pin downwards with the substrate support while the first lift pin remains stationary. In some embodiments that may be combined with other embodiments, orienting the first plane to be substantially parallel to the third plane further includes commencing downward movement of the first lift pin while the substrate support and the second lift pin continue moving downwards.

In some embodiments that may be combined with other embodiments, method 450 includes transferring the substrate between the lift pins and the substrate carrier. In some embodiments that may be combined with other embodiments, transferring the substrate between the lift pins and the substrate carrier includes transferring the substrate from the lift pins to the substrate carrier. In an example, the substrate is disposed on the upper ends of the lift pins, and the substrate support is lowered towards the first position while the lift pins move with the substrate support, and lifting the substrate off the lift pins with the substrate carrier.

In some embodiments that may be combined with other embodiments, transferring the substrate between the lift pins and the substrate carrier includes transferring the substrate from the substrate carrier to the lift pins. In an example, the substrate is disposed on the substrate carrier, and the substrate support is raised towards the second position while the lift pins move with the substrate support, and lifting the substrate off the substrate carrier with the lift pins.

In some embodiments that may be combined with other embodiments, method 450 includes raising the substrate support with the substrate thereon to a third position above the second position, and performing a processing operation on the substrate.

It is contemplated that method 400 may further incorporate any operation or aspect of method 450. It is contemplated that method 450 may further incorporate any operation or aspect of method 400. It is further contemplated that method 400 and method 450 may include any one or more of the actions, activities, aspects, or operations of the present disclosure.

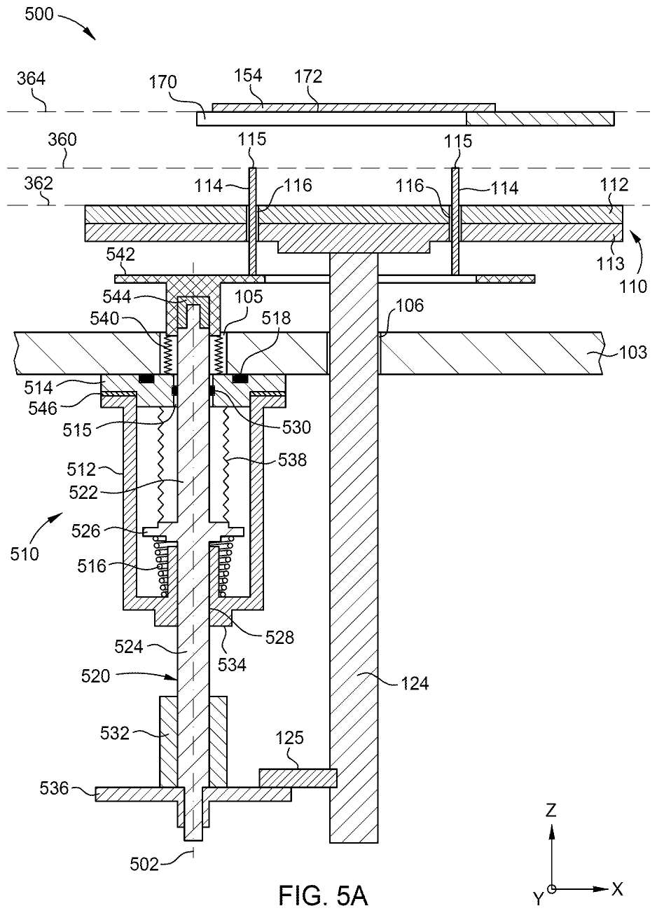

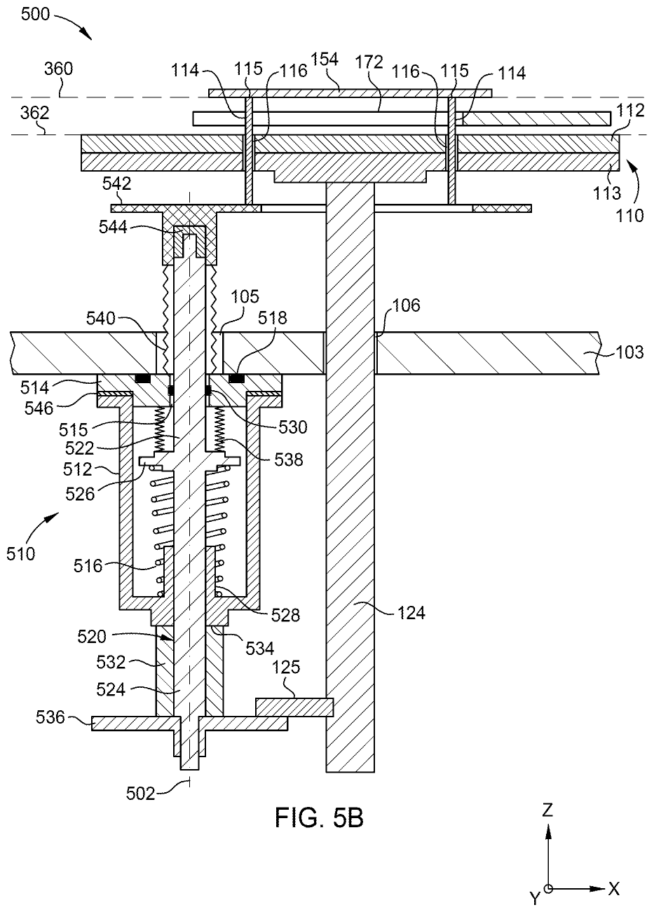

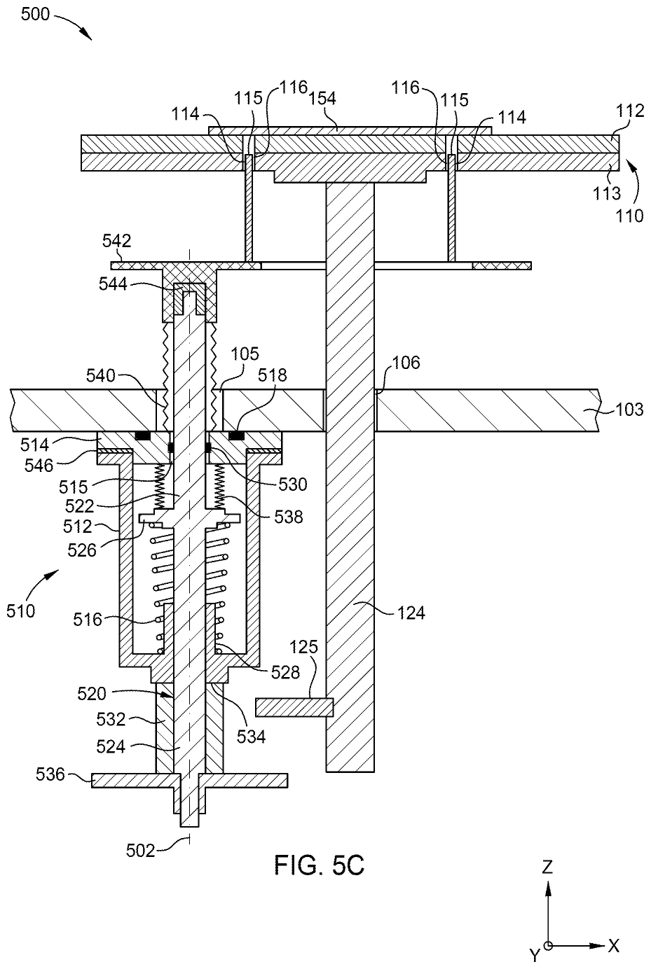

FIGS. 5A to 5C schematically illustrate a lift pin system 500 that may be used in the processing chamber 100. FIG. 5A shows the substrate support 110 in a lowered position. A substrate 154 is positioned on the carrier 170 above the substrate support 110. FIG. 5B shows the substrate support 110 in an intermediate position above the lowered position. The substrate 154 is shown having been lifted off the carrier 170. FIG. 5C shows the substrate support 110 in a raised position above the intermediate position. The substrate 154 is shown resting on the support surface 118 of the substrate support 110.

The lift pin system 500 includes a plunger assembly 510. The plunger assembly 510 includes a plunger housing 512. The plunger housing 512 is coupled to the base 103 of the processing chamber 100, such as via an adapter plate 514. A seal member 518 seals an interface between the adapter plate 514 and the base 103 of the processing chamber 100. The seal member 518 may include an o-ring, an x-ring, a lip seal, or a labyrinth seal.

A plunger 520 is disposed in the plunger housing 512. The plunger 520 is axially movable in the plunger housing 512 along a longitudinal axis 502 of the plunger assembly 510. The plunger 520 is biased in an upwards (“Z”) direction along the longitudinal axis 502, such as by a spring 516 acting against a shoulder 526 of the plunger 520. In some embodiments, the plunger 520 is biased in the upwards direction by a fluid pressure. In some embodiments, the plunger 520 is biased in the upwards direction by a magnetic field.

A lower shaft 524 of the plunger 520 extends from the shoulder 526 and through a guide 528 at a bottom of the plunger housing 512. An actuating plate 536 is coupled to the lower shaft 524 below the plunger housing 512. A bushing 532 is coupled to the lower shaft 524 between the actuating plate 536 and the plunger housing 512. In some embodiments, the bushing 532 affects a maximum upward position of the plunger 520. In an example, contact by the bushing 532 against a stop shoulder 534 at the bottom of the plunger housing 512 provides a limit to the upward movement of the plunger 520. In some embodiments, the maximum upward position of the plunger 520 may be altered by adjusting the bushing 532. In an example, the bushing 532 is adjusted by replacing the bushing 532 with another bushing 532 of a different length in the Z direction. In another example, the bushing 532 is adjusted by securing the bushing 532 to the lower shaft 524 at any one of a plurality of locations along the lower shaft 524, such as by a set screw. In some embodiments, the bushing 532 may be omitted, and the maximum upward position of the plunger 520 is determined by the actuating plate 536 contacting the stop shoulder 534.

An upper shaft 522 of the plunger 520 extends from the shoulder 526, through an aperture 515 in the adapter plate 514, and through the aperture 105 in the base 103 of the processing chamber 100 into the processing chamber 100. In some embodiments that may be combined with other embodiments, the plunger assembly 510 includes a bellows 538 around the upper shaft 522 that extends from the shoulder 526 of the plunger 520 to the adapter plate 514. The bellows 538 seals against the shoulder 526 of the plunger 520 and against the adapter plate 514.

The upper shaft 522 is coupled to a hoop plate 542. In some embodiments that may be combined with other embodiments, the plunger assembly 510 includes a bellows 540 around the upper shaft 522 that extends from the adapter plate 514 to the hoop plate 542. The bellows 540 seals against the adapter plate 514 and against the hoop plate 542.

In some embodiments that may be combined with other embodiments, the plunger assembly 510 includes the bellows 538 and the bellows 540. In some embodiments, the plunger assembly 510 includes the bellows 538, but the bellows 540 is omitted. In some embodiments, the plunger assembly 510 includes the bellows 540, but the bellows 538 is omitted. In some embodiments, the bellows 538 and the bellows 540 are omitted. In some of such embodiments, a seal member 530 in the adapter plate 514 provides a seal around the upper shaft 522 of the plunger 520. The seal member 530 may include an o-ring, an x-ring, a lip seal, or a labyrinth seal. In embodiments in which at least one of bellows 538 or bellows 540 is present, the seal member 530 may be omitted.

The bellows 538, the bellows 540, or the seal member 530 isolates the interface between the lower shaft 524 of the plunger 520 and the guide 528 from the environment in the processing volume 150 of the processing chamber 100.

In some embodiments, the shoulder 526 of the plunger 520 has an outer diameter greater than an outer diameter of the upper shaft 522 of the plunger 520. In some embodiments, the shoulder 526 has an outer diameter greater than an outer diameter of the lower shaft 524 of the plunger 520. In some embodiments, the upper shaft 522, the shoulder 526, and the lower shaft 524 are integrally formed. The outer diameter of the shoulder 526 is greater than a diameter of the aperture 515 of the adapter plate 514. The outer diameter of the shoulder 526 is greater than an inner diameter of the guide 528 at the bottom of the plunger housing 512.

In some embodiments that may be combined with other embodiments, a clearance between the upper shaft 522 of the plunger 520 and the aperture 515 in the adapter plate 514 is greater than a clearance between the lower shaft 524 and the guide 528. In such embodiments, the guide 528 directs axial movement of the plunger 520 in the Z direction while inhibiting rubbing contact between the upper shaft 522 and the adapter plate 514. The inhibition of rubbing contact between the upper shaft 522 and the adapter plate 514 hinders the detrimental formation of debris particles around the upper shaft 522 in the aperture 515 in the adapter plate 514.

In some embodiments that may be combined with other embodiments, a clearance between the upper shaft 522 and the aperture 105 in the base 103 of the processing chamber 100 is greater than a clearance between the lower shaft 524 and the guide 528. In such embodiments, the guide 528 directs axial movement of the plunger 520 in the Z direction while inhibiting rubbing contact between the upper shaft 522 and the base 103 of the processing chamber 100. The inhibition of rubbing contact between the upper shaft 522 and the base 103 of the processing chamber 100 hinders the detrimental formation of debris particles around the upper shaft 522 in the aperture 105 in the base 103 of the processing chamber 100.

The hoop plate 542 includes an annular body that extends in the X and Y directions. The hoop plate 542 is cantilevered from the connection with the upper shaft 522 of the plunger 520 at the upper end of the upper shaft 522. In some embodiments that may be combined with other embodiments, a droop of the hoop plate 542 may be compensated by including a shim 544 at the connection of the hoop plate 542 with the upper end of the upper shaft 522. In some embodiments that may be combined with other embodiments, a droop of the hoop plate 542 may be compensated by including a shim 546 at the connection of the adapter plate 514 with the plunger housing 512. The shim 544 or the shim 546 may shift the longitudinal axis 502 of the plunger assembly 510 by 1 degree or less, 0.5 degrees or less, 0.25 degrees or less, 0.1 degrees or less, or 0.05 degrees or less.

A plurality of lift pins 114 is disposed on the hoop plate 542. It is contemplated that the lift pin system 500 includes three lift pins 114, but may contain more than three lift pins 114, such as four, five, six, or more lift pins 114. In some embodiments, the lift pins 114 include a lift pin configured as one of lift pin 260, lift pin 271, or lift pin 271A. Each lift pin 114 is disposed through a corresponding hole 116 in the substrate support 110. The substrate support 110 is disposed on the support shaft 124. The support shaft 124 extends through the aperture 106 in the base 103 of the processing chamber 100, and is configured to raise and lower the substrate support 110 in the Z direction.

An actuating arm 125 is coupled to the support shaft below the base 103 of the processing chamber 100. The actuating arm 125 extends laterally from the support shaft 124, and is movable in the Z direction with the support shaft 124. Contact by the actuating plate 536 against the actuating arm 125 provides a limit to the upward movement of the plunger 520 when the bushing 532 is out of contact with the stop shoulder 534 at the bottom of the plunger housing 512.

FIGS. 5A to 5C schematically illustrate an operational sequence in which the substrate 154 is brought into the processing chamber 100 on the carrier 170, and then transferred from the carrier 170 to the substrate support 110. The upper end 115 (such as a tip) of each lift pin 114 lies on, and defines, the lift pin plane 360 (as described above). The lift pin system 500 may be adjusted, such as described above, to alter an orientation of the lift pin plane 360. The upper surface 172 of the carrier 170, on which the substrate 154 is transported into and out of the processing chamber 100, lies on, and defines, the carrier plane 364 (as described above). The support surface 118 of the substrate support 110 lies on, and defines, the support plane 362 (as described above).

FIG. 5A shows the substrate support 110 in the lowered position. The substrate 154 is disposed on the upper surface 172 of the carrier 170 above the substrate support 110. It is contemplated that the substrate 154 lies on or parallel to the carrier plane 364. The upper ends 115 of each lift pin 114 are spaced below the substrate 154 and above the support surface 118 of the substrate support 110. The spring 516 in the plunger housing 512 biases the plunger 520 upwards along the longitudinal axis 502 of the plunger assembly 510. The actuating plate 536 is biased upwards into contact with the actuating arm 125 such that the actuating arm 125 limits upward movement of the actuating plate 536, the plunger 520, the hoop plate 542, and the lift pins 114.

In some embodiments that may be combined with other embodiments, the orientation of the lift pin plane 360 is altered to be substantially parallel to the carrier plane 364. For example, the lift pin plane 360 is altered such that an angle between the lift pin plane 360 and the carrier plane 364 is 1 degree or less, 0.5 degrees or less, 0.25 degrees or less, 0.1 degrees or less, 0.05 degrees or less, or 0 degrees. In some embodiments, the orientation of the lift pin plane 360 is substantially parallel to the carrier plane 364 prior to the lift pins 114 contacting the substrate 154 that is on the carrier 170.

In some embodiments that may be combined with other embodiments, the orientation of the lift pin plane 360 is altered by adjusting the shim 544. In some embodiments that may be combined with other embodiments, the orientation of the lift pin plane 360 is altered by adjusting the shim 546.

FIG. 5B shows the substrate support 110 in the intermediate position above the lowered position. The support shaft 124 has moved the substrate support 110 upwards with respect to the base 103 of the processing chamber 100. The spring 516 in the plunger housing 512 has biased the plunger 520 to move upwards along the longitudinal axis 502 of the plunger assembly 510. The actuating arm 125 has moved upwards with the support shaft 124, allowing the plunger 520 to move upwards. Upward movement of the plunger 520 has moved the hoop plate 542 and the lift pins 114 upwards.

The plunger 520 is illustrated in a maximum upward position. Further upward movement of the plunger 520 is prevented by the bushing 532 coupled to the lower shaft 524 of the plunger 520 contacting the stop shoulder 534 at the bottom of the plunger housing 512.

The substrate 154 is shown having been lifted off the carrier 170 by the lift pins 114. The substrate 154 rests on the upper ends 115 of the lift pins 114. In some embodiments that may be combined with other embodiments, transfer of the substrate 154 from the carrier 170 to the lift pins 114 is performed without changing an elevation of the carrier 170 (i.e., in the Z direction) within the processing chamber 100. After lifting the substrate 154 off the carrier 170, the carrier 170 is removed from the processing chamber 100.

FIG. 5C shows the substrate support 110 in the raised position above the intermediate position. The support shaft 124 has moved the substrate support 110 upwards with respect to the base 103 of the processing chamber 100. The plunger 520, hoop plate 542, and lift pins 114 have not moved upwards. Upward movement of the plunger 520 remains prevented by the bushing 532 coupled to the lower shaft 524 of the plunger 520 contacting the stop shoulder 534 at the bottom of the plunger housing 512. The upper ends 115 of the lift pins 114 are now below the support surface 118 of the substrate support 110, and the substrate 154 has been placed onto the support surface 118.

In some embodiments, the raised position of the substrate support 110 depicted in FIG. 5C represents the position of the substrate support 110 during processing of the substrate 154. In some embodiments, the substrate support 110 is further raised above the position depicted in FIG. 5C to a processing position at which processing of the substrate 154 is conducted. As illustrated, in some embodiments, when the substrate support 110 is in the raised position, the lift pins 114 remain in contact with the hoop plate 542. In some embodiments, when the substrate support 110 is in the raised position, the lift pins 114 are lifted off of the hoop plate 542. In some embodiments, when the substrate support 110 is in the processing position, the lift pins 114 remain in contact with the hoop plate 542. In some embodiments, when the substrate support 110 is in the processing position, the lift pins 114 are lifted off of the hoop plate 542.

In some embodiments that may be combined with other embodiments, the orientation of the lift pin plane 360 is altered to be substantially parallel to the support plane 362. For example, the lift pin plane 360 is altered such that an angle between the lift pin plane 360 and the support plane 362 is 1 degree or less, 0.5 degrees or less, 0.25 degrees or less, 0.1 degrees or less, 0.05 degrees or less, or 0 degrees. In some embodiments, the orientation of the lift pin plane 360 is substantially parallel to the support plane 362 prior to the substrate support 110 lifting the substrate off the lift pins 114.

In some embodiments that may be combined with other embodiments, the orientation of the lift pin plane 360 is altered by adjusting the shim 544. In some embodiments that may be combined with other embodiments, the orientation of the lift pin plane 360 is altered by adjusting the shim 546.

The transfer of the substrate 154 from the substrate support 110 to the carrier 170 involves performing the above operations in reverse. The support shaft 124 moves the substrate support 110 downwards from the raised position of FIG. 5C towards the intermediate position of FIG. 5B. The lift pins 114, hoop plate 542, and plunger 520 do not move in the Z direction while the support shaft 124 moves the substrate support 110 downwards from the raised position of FIG. 5C towards the intermediate position of FIG. 5B. The lift pins 114 emerge through the holes 116 in the substrate support 110, and lift the substrate 154 off the support surface 118. In some embodiments, the orientation of the lift pin plane 360 is substantially parallel to the support plane 362 prior to the lift pins 114 lifting the substrate 154 off the substrate support 110. The carrier 170 is then positioned between the substrate 154 and the support surface 118.

When the substrate support 110 is at or near the intermediate position, the actuating arm 125 contacts the actuating plate 536. When the support shaft 124 moves the substrate support 110 downwards from the intermediate position of FIG. 5B to the lowered position of FIG. 5A, the engagement of the actuating arm 125 with the actuating plate 536 causes the actuating plate 536 to move downwards. Downward movement of the actuating plate 536 causes a similar downward movement of the plunger 520, the hoop plate 542, and the lift pins 114. The lift pins 114 move downward with the substrate support 110 relative to the carrier 170. The substrate 154 is then transferred from the lift pins 114 to the carrier 170. In some embodiments, the carrier 170 lifts the substrate 154 off the lift pins 114. In some embodiments, the lift pins 114 deposit the substrate 154 onto the carrier 170. In some embodiments, the orientation of the lift pin plane 360 is substantially parallel to the carrier plane 364 prior to the carrier 170 lifting the substrate 154 off the lift pins 114. In some embodiments that may be combined with other embodiments, transfer of the substrate 154 from the lift pins 114 to the carrier 170 is performed without changing an elevation of the carrier 170 (i.e., in the Z direction) within the processing chamber 100. The carrier 170 may then transport the substrate 154 out of the processing chamber 100.

In some embodiments, one or more adjustments to the lift pin system 500 are made prior to transferring a substrate 154 into the processing chamber 100 for processing. In an example, the one or more adjustments are made during an initial setting-up of the processing chamber 100 prior to processing a batch of substrates 154. In another example, the one or more adjustments are made during the processing of a batch of substrates 154, such as during a pause in the processing of the batch of substrates 154. In another example, the one or more adjustments are made after processing a first batch of substrates 154 and before processing a second batch of substrates 154.

In some embodiments that may be combined with other embodiments, the one or more adjustments to the lift pin system 500 include one or more adjustments that alter the orientation of the lift pin plane 360, described above.

In some embodiments that may be combined with other embodiments, the one or more adjustments include changing the maximum upward position of the plunger 520. In an example, the maximum upward position of the plunger 520 is changed by adjusting the bushing 532 coupled to the lower shaft 524 of the plunger 520, such as described above. In some embodiments that may be combined with other embodiments, the one or more adjustments include installing a shim 544 at the coupling of the hoop plate 542 with the upper shaft 522 of the plunger 520. In some embodiments that may be combined with other embodiments, the one or more adjustments include installing a shim 544 at the coupling of the adapter plate 514 with the plunger housing 512.

Embodiments of the present disclosure facilitate the transfer of a substrate between a carrier and a substrate support without changing an elevation of the carrier within a processing chamber. Embodiments of the present disclosure facilitate the actuation of lift pins by using motion of a substrate support. Embodiments of the present disclosure facilitate the actuation of a plurality of lift pins such that the lift pins simultaneously contact the substrate, and then raise the substrate. Embodiments of the present disclosure facilitate the actuation of a plurality of lift pins such that lateral movement of the lift pins is hindered. Embodiments of the present disclosure facilitate the actuation of a plurality of lift pins such that unwanted lateral movement of a substrate resting on the lift pins is hindered.

Embodiments of the present disclosure facilitate the transfer of a substrate from a carrier to a plurality of lift pins such that the lift pins simultaneously contact the substrate, and simultaneously lift the substrate off the carrier. Embodiments of the present disclosure facilitate the transfer of a substrate from a plurality of lift pins to a substrate support such that the substrate support lifts the substrate off each lift pin simultaneously. Embodiments of the present disclosure facilitate the transfer of a substrate from a substrate support to a plurality of lift pins such that the lift pins simultaneously contact the substrate, and simultaneously lift the substrate off the substrate support. Embodiments of the present disclosure facilitate the transfer of a substrate from a plurality of lift pins to a carrier such that the carrier lifts the substrate off each lift pin simultaneously.

It is contemplated that any one or more elements or features of any one disclosed embodiment may be beneficially incorporated in any one or more other non-mutually exclusive embodiments. While the foregoing is directed to embodiments of the present disclosure, other and further embodiments of the disclosure may be devised without departing from the basic scope thereof, and the scope thereof is determined by the claims that follow.

What is claimed is:

1. A lift pin system, comprising:
a plunger disposed in a plunger housing;
a lift pin disposed in a lift pin housing above the plunger housing, the lift pin axially movable by movement of the plunger, and including:
an upper end extending out of a top of the lift pin housing; and
a lower end extending out of a bottom of the lift pin housing; and
a seal member disposed in the lift pin housing, the seal member configured to form a seal against the lift pin.

2. The lift pin system of claim 1, wherein the seal member is configured to form a seal against one of a shoulder of the lift pin or a shaft of the lift pin.

3. The lift pin system of claim 1, wherein the seal member includes an o-ring, an x-ring, a lip seal, or a labyrinth seal.

4. The lift pin system of claim 1, wherein the lift pin includes a lower shaft and an upper shaft separated by a shoulder.

5. The lift pin system of claim 4, wherein the upper shaft is movable with respect to the lower shaft.

6. The lift pin system of claim 1, wherein the lift pin is biased towards the plunger by a spring.

7. The lift pin system of claim 6, wherein the spring is conical.

8. A lift pin system, comprising:
a lift pin disposed in a lift pin housing, the lift pin including:
an upper end extending out of a top of the lift pin housing; and
a lower end extending out of a bottom of the lift pin housing;
a weight disposed at the lower end; and
a conical spring disposed between the weight and the lift pin housing.

9. The lift pin system of claim 8, further comprising a seal member disposed in the lift pin housing, and configured to form a seal against the lift pin.

10. The lift pin system of claim 9, wherein the seal member is configured to form a seal against one of a shoulder of the lift pin or a shaft of the lift pin.

11. The lift pin system of claim 9, wherein the seal member includes an o-ring, an x-ring, a lip seal, or a labyrinth seal.

12. The lift pin system of claim 8, wherein the lift pin includes a lower shaft and an upper shaft separated by a shoulder.

13. The lift pin system of claim 12, wherein the upper shaft is movable with respect to the lower shaft.

14. A substrate processing chamber, comprising:
a chamber body including a base;
a substrate support disposed within the chamber body; and
a lift pin system, comprising:
a plunger housing coupled to the base;
a plunger disposed in the plunger housing;
a lift pin housing above the plunger housing, and coupled to the substrate support;
a lift pin disposed in the lift pin housing, the lift pin axially movable by movement of the plunger, and including:
an upper end extending out of a top of the lift pin housing; and
a lower end extending out of a bottom of the lift pin housing; and
a seal member in the lift pin housing, the seal member configured to form a seal against the lift pin.

15. The substrate processing chamber of claim 14, wherein the lift pin system further comprises a weight disposed at the lower end of the lift pin.

16. The substrate processing chamber of claim 15, wherein the lift pin system further comprises a conical spring disposed between the weight and the lift pin housing, the conical spring biasing the lift pin towards the plunger.

17. The substrate processing chamber of claim 14, wherein the seal member is configured to form a seal against one of a shoulder of the lift pin or a shaft of the lift pin.

18. The substrate processing chamber of claim 14, wherein the seal member includes an o-ring, an x-ring, a lip seal, or a labyrinth seal.

19. The substrate processing chamber of claim 14, wherein the lift pin includes a lower shaft and an upper shaft separated by a shoulder.

20. The substrate processing chamber of claim 19, wherein the upper shaft is movable with respect to the lower shaft.
